(19) United States
(12) Patent Application Publication
(10) Pub. No.: US 2026/0334255 A1
(43) Pub. Date: Oct. 22, 2026

(54) CIRCUIT BOARD AND SEMICONDUCTOR PACKAGE COMPRISING SAME

(71) Applicant: LG INNOTEK CO., LTD., Seoul (KR)

(72) Inventors: Sung Min KIM, Seoul (KR); Eun Young KONG, Seoul (KR); See Yoon HWANG, Seoul (KR)

(73) Assignee: LG INNOTEK CO., LTD., Seoul (KR)

(21) Appl. No.: 19/104,738

(22) PCT Filed: Aug. 23, 2023
(86) PCT No.: PCT/KR2023/012495

§ 371 Date: Feb. 19, 2025

(30) Foreign Application Priority Data
Aug. 23, 2022 (KR) 10-2022-0105318
Aug. 24, 2022 (KR) 10-2022-0105922
Aug. 30, 2022 (KR) 10-2022-0109537

(51) Int. Cl. H10W 70/63

(52) U.S. Cl. CPC H10W 70/635

(57) ABSTRACT

A circuit board according to an embodiment includes an insulating layer; and a circuit layer disposed on the insulating layer and having a lower surface contacting the insulating layer and an upper surface facing the lower surface, wherein the circuit layer includes a plurality of through holes passing through the upper surface and the lower surface, and wherein a diameter of each of the plurality of through holes equal to or greater than a separation distance between two through holes disposed adjacent to each other among the plurality of through holes.

### TECHNICAL FIELD

An embodiment relates to a circuit board and a semiconductor package including the same.

### BACKGROUND ART

As performances of electric/electronic products progresses, technologies for disposing a greater number of semiconductor devices on a semiconductor package substrate of a limited size are being proposed and studied. However, since a general semiconductor package is based on mounting a single semiconductor device, there is a limit to obtaining a desired performance.

Accordingly, a semiconductor package that mounts a plurality of semiconductor devices using a plurality of circuit boards has been recently provided. This semiconductor package has a structure in which a plurality of semiconductor devices are connected to each other in a horizontal direction and/or a vertical direction on the circuit board. Accordingly, the semiconductor package has the advantage of efficiently using a mounting area of the semiconductor devices and transmitting high-speed signals through a short signal transmission path between the semiconductor devices.

In addition, semiconductor packages applied to products that provide the Internet of Things (IoT), autonomous vehicles, and high-performance servers are expanding a concept to semiconductor chiplets as a number of semiconductor devices and/or a size of each semiconductor device increases in accordance with a trend of high integration, or as functional parts of the semiconductor devices are divided.

On the other hand, as the number of semiconductor devices and/or semiconductor chipsets mounted on a semiconductor package increases, areas of circuit boards and semiconductor packages tend to increase. In addition, as the area of the circuit board and the semiconductor package increases, the area and/or wiring density of the circuit layer provided on the circuit board also increases. When the area and/or wiring density of the circuit layer increases, a problem occurs in that gas generated from the insulating layer in contact with the circuit layer is not sufficiently discharged, and thus a surface of the insulating layer and/or the circuit layer may swell due to the gas that has not been discharged. Accordingly, a mechanical reliability problem in which the insulating layer and/or the circuit layer is peeled off may occur.

### DISCLOSURE

### Technical Problem

An embodiment provides a circuit board having a new structure and a semiconductor package including the same.

In addition, an embodiment provides a circuit board with improved adhesion between an insulating layer and a circuit layer and a semiconductor package including the same.

In addition, an embodiment provides a circuit board with improved gas exhaust characteristics and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises an insulating layer; and a circuit layer disposed on the insulating layer and having a lower surface contacting the insulating layer and an upper surface facing the lower surface, wherein the circuit layer includes a plurality of through holes passing through the upper surface and the lower surface, and wherein a diameter of each of the plurality of through holes equal to or greater than a separation distance between two through holes disposed adjacent to each other among the plurality of through holes.

In addition, diameters of each of the plurality of through holes are different from each other, a separation distance between two of the plurality of through-holes disposed adjacent to each other is different from each other, and a diameter of a smallest through hole among the plurality of through holes is equal to or greater than a largest separation distance among separation distances between two through holes disposed adjacent to each other.

In addition, a ratio of the diameter of the through hole to a planar area of the insulating layer satisfies a range of 0.0000825 to 0.000147.

In addition, a ratio of a planar area of the through hole to a planar area of the insulating layer satisfies a range of 0.00025905 to 0.0004605.

In addition, a planar area of the insulating layer is 1500 mm² to 2000 mm2.

In addition, at least one of the plurality of through holes has a diameter of 165 μm to 220 μm.

In addition, a planar area of at least one of the plurality of through holes satisfies a range of 518.1 μm² to 690.8 μm².

In addition, the circuit layer includes a plurality of circuit patterns spaced apart in a horizontal direction, the plurality of through holes are provided in the plurality of circuit patterns, respectively, and a spacing between the plurality of circuit patterns is smaller than the diameter of the through hole.

In addition, the circuit board further comprises a through electrode passing through the insulating layer and connected to the circuit layer, and wherein the diameter of the through hole is greater than a width of the through electrode in a horizontal direction.

In addition, each of the plurality of through holes is not connected to an outer surface of the circuit layer and does not overlap the through electrode in a vertical direction.

In addition, the diameter of the through hole is 2.5 times or more of the width of the through electrode.

In addition, the insulating layer is made up of a plurality of layers, the circuit layer is disposed on a uppermost layer, and the through hole of the circuit layer is filled with a protective layer disposed on the circuit layer.

In addition, the insulating layer includes a first insulating layer and a second insulating layer disposed on the first insulating layer, the circuit layer is disposed between the first and second insulating layers, and the through hole is filled with the second insulating layer.

In addition, the circuit board includes a plurality of circuit layers spaced apart in the vertical direction, and each of the ratios is a ratio of through holes provided in any one of the circuit layers.

Furthermore, the circuit board of the embodiment comprises an insulating layer; and a first circuit layer disposed on an upper surface of the insulating layer; the first circuit layer is divided into first and second regions along a horizontal direction; the first region of the first circuit layer includes a plurality of first through holes passing through upper and lower surfaces of the first circuit layer; the second region of the first circuit layer includes a plurality of second through holes passing through upper and lower surfaces of the first circuit layer; and a diameter of each of the plurality of first through holes is smaller than a diameter of each of the plurality of second through holes.

In addition, the circuit board further comprises a second circuit layer disposed on a lower surface of the insulating layer, the second circuit layer includes first circuit patterns vertically overlapping the first region of the first circuit layer, and second circuit patterns vertically overlapping the second region of the first circuit layer, and a wiring density of the first circuit patterns is different from a wiring density of the second circuit patterns.

In addition, the wiring density of the second circuit patterns is greater than that of the first circuit patterns.

In addition, the second circuit patterns include an impedance matching circuit pattern for impedance matching.

In addition, a separation distance between two closest first through holes among the plurality of first through holes is greater than a separation distance between two closest second through holes among the plurality of second through holes.

In addition, the first circuit layer is further divided into a third region corresponding to an edge region of the upper surface of the first circuit layer, and the third region of the first circuit layer includes a plurality of third through holes passing through upper and lower surfaces of the first circuit layer.

In addition, a diameter of the third through hole is smaller than a diameter of each of the first and second through holes.

In addition, a separation distance between two closest third through holes is greater than a separation distance between two closest first through holes and a separation distance between two closest second through holes.

In addition, the diameter of each of the plurality of first through holes is greater than or equal to a separation distance between two first through holes disposed closest to each other among the plurality of first through holes.

In addition, two first through holes disposed closest to each other are two first through holes located in a diagonal horizontal direction from each other in the first circuit layer.

In addition, diameters of the plurality of first through holes are different from each other, a diameter of each of the plurality of first through holes is different from a separation distance between two first through holes disposed adjacent to each other, and a smallest diameter of the plurality of first through holes is more than a largest separation distance between two first through holes disposed adjacent to each other.

In addition, a ratio of the diameter of the first through hole to a planar area of the insulating layer satisfies a range of 0.0000825 to 0.000147.

In addition, a ratio of a planar area of the first through hole to a planar area of the insulating layer satisfies a range of 0.00025905 to 0.0004605.

In addition, the ratio is a ratio to the first through hole provided in a single circuit layer disposed on the insulating layer.

In addition, the planar area of the insulating layer is 1500 mm² to 2000 mm².

In addition, at least one of the plurality of first through holes has a diameter of 165 μm to 220 μm.

In addition, a planar area of at least one of the plurality of first through holes satisfies the range of 518.1 μm² to 690.8 μm².

In addition, the circuit board further comprises a through electrode passing through the insulating layer, and a width of the through electrode is different from a diameter of each of the first to third through holes.

In addition, the through electrode has an inclination that gradually changes in width from an upper surface toward a lower surface of the insulating layer, and a diameter of each of the first to third through holes is greater than a width of a region having a largest width in the through electrode.

In addition, each of the first to third through holes does not vertically overlap the through electrode.

In addition, the first circuit layer includes a fourth through hole vertically overlapping the through electrode; and a pad disposed inside the fourth through hole, and a diameter of the fourth through hole is smaller than the diameter of each of the first through third through holes.

In addition, a circuit pattern is not provided in inner regions of the first to third through holes, and the inner regions of the first to third through holes are filled with other insulating layers or protective layers disposed on the insulating layers.

### Advantageous Effects

The semiconductor package of the embodiment may include an insulating layer and a circuit layer disposed on the insulating layer. At this time, the circuit layer may include at least one through hole. That is, the circuit layer may include a plurality of circuit patterns spaced apart in a horizontal direction. In addition, the through hole may have a different meaning from a space between the plurality of circuit patterns. That is, the through hole may mean a through hole passing through upper and lower surfaces of each circuit pattern.

Accordingly, the embodiment may use the through hole provided in the circuit layer to allow gas generated in the insulating layer to be well exhausted onto the circuit layer. Through this, the embodiment may prevent the insulating layer and/or the circuit layer from swelling due to the gas. Accordingly, the embodiment may improve an adhesion between the plurality of insulating layers and an adhesion between the insulating layer and the circuit layer. Through this, the embodiment may improve the physical reliability of a circuit board.

In addition, the circuit layer of the embodiment may be provided with a plurality of through holes. At this time, a diameter W3 of each of the plurality of through holes provided in the circuit layer may be greater than or equal to a separation distance between two mutually adjacent through holes among the plurality of through holes. In other words, the diameter of each of the plurality of through holes provided in the circuit layer may be equal to or greater than the separation distance between two mutually adjacent through holes among the plurality of through holes.

At this time, if the diameter of each of the plurality of through holes is smaller than the separation distance between two mutually adjacent through holes among the plurality of through holes, the gas generated in the insulating layer may not be easily exhausted to an outside of the circuit board. In other words, a fact that the diameter is smaller than the separation distance may mean that, based on a region where the through holes are disposed in the circuit layer, the region where the gas cannot be exhausted through the through holes is larger than the region where the gas can be exhausted. In addition, if the diameter of the through hole is smaller than the separation distance between the plurality of through holes, the gas may not be exhausted well and may remain in the insulating layer, which may result in deterioration of the physical characteristics.

Therefore, the embodiment allow each diameter of the plurality of through holes provided in the circuit layer to be equal to or greater than the separation distance between two adjacent through holes among the plurality of through holes. Accordingly, the embodiment can completely exhaust the gas without the gas remaining in the insulating layer. Therefore, the embodiment can further improve the physical characteristics of the circuit board and the semiconductor package.

Meanwhile, at this time, the diameter of at least one of the plurality of through holes may be different from at least one other diameter. The separation distances of the plurality of through holes adjacent to each other may be different from each other. At this time, the embodiment allows the diameter of the through hole having a smallest diameter among the plurality of through holes to be equal to or greater than a largest separation distance among the plurality of adjacent through holes. Through this, the embodiment can further improve the physical reliability of the circuit board and the semiconductor package by allowing the gas generated in the insulating layer to be exhausted better.

In addition, the circuit layer of the embodiment is provided with a plurality of through holes. At this time, the diameter of at least one of the plurality of through holes may be determined based on a planar area of a circuit board and/or the insulating layer.

For example, a ratio of the diameter of the through hole to a planar area of the insulating layer can satisfy a range of 0.0000825 to 0.000147. In addition, a ratio of the planar area of the through hole to a planar area of the insulating layer can satisfy a range of 0.00025905 to 0.0004605. At this time, the planar area of the insulating layer can be 1500 mm² to 2000mm² . In addition, at least one of the plurality of through holes can have a diameter of 165 μm to 220 μm. In addition, the planar area of at least one of the plurality of through holes can satisfy a range of 518.1 μm² to 690.8 μm² . In addition, the embodiment allows the diameter of at least one of the plurality of through holes provided in the circuit layer to be 165 μm or more. In this case, the diameter of at least one of the plurality of through holes provided in the circuit layer can be 165 μm or more. That is, if the diameter of the through hole is smaller than 165 μm, the gas generated from the insulating layer having the planar area may not be properly exhausted to an upper side of the circuit layer. In addition, when the gas is not exhausted, the adhesion may be reduced due to swelling of the circuit layer and/or the insulating layer. Therefore, the embodiment can ensure that at least one through hole among the plurality of through holes has a diameter of 165 μm or more, so that the gas generated from the insulating layer can be properly exhausted, and thus the physical characteristics can be further improved.

In addition, the diameter of the through hole may be 220 μm or less. Preferably, if the diameter of the through hole exceeds 220 μm, the impedance characteristics between the plurality of circuit layers may change. In addition, if the diameter of the through hole exceeds 220 μm, the density and/or area of the circuit layer may decrease, and thus the circuit board and semiconductor package may be significantly warped in a specific direction. Accordingly, the embodiment can improve the rigidity of the circuit board and the semiconductor package while preventing the impedance characteristics between the multiple circuit layers from changing by making the diameter of the through hole 220 μm or less.

In addition, the through hole of the circuit layer may not vertically overlap with the through electrode passing through the insulating layer. In other words, the through electrode may mean a through electrode directly connected to the circuit layer. In addition, the through electrode directly connected to the circuit layer may not vertically overlap with the through hole. Accordingly, the embodiment may allow the gas generated in the insulating layer to be well exhausted without deteriorating the electrical signal transmission characteristics of the through electrode.

In addition, the through hole of the circuit layer may be larger than a width of a region having a largest width in the through electrode. Through this, the embodiment can further improve the gas exhaust characteristics by the through hole of the circuit layer.

Meanwhile, the circuit layer of the embodiment may include a first circuit layer disposed on an insulating layer and a second circuit layer disposed under the insulating layer. At this time, the first circuit layer may be divided into a plurality of regions. For example, the first circuit layer may include a first and a second region. The first region of the first circuit layer may be a region that vertically overlaps with first electrode patterns of the second circuit layer. The second region of the second circuit layer may be a region that vertically overlaps with second electrode patterns of the second circuit layer. In addition, the first circuit layer may include a third region that is closer to an edge of the first circuit layer than the first and second regions.

At this time, the first to third regions of the first circuit layer may each be provided with a through hole. For example, the first region of the first circuit layer may be provided with a plurality of first through holes. For example, the second region of the first circuit layer may be provided with a plurality of second through holes. For example, the third region of the first circuit layer may be provided with a plurality of third through holes. At this time, a diameter of the first through hole provided in the first circuit pattern, a diameter of the second through hole provided in the second circuit pattern, and a diameter of the third through hole provided in the third circuit pattern may be different from each other.

Preferably, the second electrode patterns of the second circuit layer may have a higher wiring density than other circuit patterns of the second circuit layer. For example, the second circuit patterns of the second circuit layer may include a circuit pattern for impedance matching.

Accordingly, the diameter of the second through hole provided in the second region of the first circuit layer may be larger than the diameters of each of the first and third through holes. Through this, in the embodiment, more smooth gas exhaust can be achieved in the region vertically overlapping with the second circuit patterns of the second circuit layer, which has a high wiring density among the entire region of the insulating layer. Furthermore, in the embodiment, the diameter of the second through hole provided in the second region of the second circuit layer is made larger than the diameters of other through holes, so that a metal ratio in the second region can be lowered. Through this, the embodiment can prevent the impedance characteristics of the second circuit pattern of the second circuit layer from changing due to the first circuit layer. Through this, the embodiment can further improve the physical reliability and/or electrical characteristics of the semiconductor package.

Meanwhile, the third region of the first circuit layer can be disposed on an edge region of the insulating layer. At this time, the diameter of the third through hole provided in the third region of the first circuit layer can be smaller than each diameter of the first through hole and the second through hole. Through this, the embodiment can secure the rigidity of the circuit board and the semiconductor package by the third region of the first circuit layer. Through this, the embodiment can further improve the physical characteristics and electrical characteristics of the circuit board.

At this time, the diameter of each of the first through hole, the second through hole, and the third through hole can be larger than the width of the through electrode passing through the insulating layer. Through this, the embodiment can completely remove gas that may remain in the insulating layer, and accordingly, the adhesion between the insulating layer and the circuit layer can be further improved.

In addition, a separation distance between two adjacent second through holes among the plurality of second through holes may be smaller than a separation distance between two adjacent first through holes among the plurality of first through holes and a separation distance between two adjacent third through holes among the plurality of third through holes, respectively. In addition, a separation distance between two adjacent third through holes among the plurality of third through holes may be larger than a separation distance between two adjacent first through holes among the plurality of first through holes and a separation distance between two adjacent second through holes among the plurality of second through holes. Accordingly, the embodiment can further improve adhesion between the insulating layer and the circuit layer while preventing the circuit board from being warped in a specific direction without changing characteristics (e.g., impedance characteristics) of the circuit layer.

### DESCRIPTION OF DRAWINGS

FIG. 1a is a cross-sectional view showing a semiconductor package according to a first embodiment.

FIG. 1b is a cross-sectional view showing a semiconductor package according to a second embodiment.

FIG. 1c is a cross-sectional view showing a semiconductor package according to a third embodiment.

FIG. 1d is a cross-sectional view showing a semiconductor package according to a fourth embodiment.

FIG. 1e is a cross-sectional view showing a semiconductor package according to a fifth embodiment.

FIG. 1f is a cross-sectional view showing a semiconductor package according to a sixth embodiment.

FIG. 1g is a cross-sectional view showing a semiconductor package according to a seventh embodiment.

FIG. 2 is a cross-sectional view illustrating a circuit board according to a first embodiment.

FIG. 3 is a plan view illustrating some layers of the circuit board of FIG. 2.

FIG. 4 is a plan view for explaining a relationship between a through electrode and a through hole in a plan view of FIG. 3.

FIGS. 5 and 6 are diagrams for explaining adhesion characteristics of circuit boards of the comparative example and the first embodiment.

FIG. 7 is a plan view for explaining a modified example of the circuit board of FIG. 3.

FIG. 8 is a plan view illustrating some layers of the circuit board of FIG. 2 according to a second embodiment.

FIG. 9 is a plan view illustrating some layers of the circuit board of FIG. 2 according to a third embodiment.

FIG. 10 is a plan view for explaining a relationship between a through electrode and a through hole in a plan view of FIG. 8.

FIG. 11 is an enlarged view of some layers of the circuit board of FIG. 2 according to a fourth embodiment.

FIG. 12 is a plan view for explaining diameters of a plurality of through holes provided in a first circuit layer of FIG. 11.

FIG. 13 is a plan view for explaining a wiring density of a second circuit layer of FIG. 11.

FIG. 14 is a plan view for explaining a relationship between a through electrode and a through hole in a plan view of FIG. 12.

### BEST MODE

Hereinafter, embodiments of the present disclosure will be described in detail with reference to the accompanying drawings.

However, the spirit and scope of the present disclosure is not limited to a part of the embodiments described, and may be implemented in various other forms, and within the spirit and scope of the present disclosure, one or more of the elements of the embodiments may be selectively combined and redisposed.

In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art. In addition, the terms used in the embodiments of the present disclosure are for describing the embodiments and are not intended to limit the present disclosure.

In this specification, the singular forms may also include the plural forms unless specifically stated in the phrase, and may include at least one of all combinations that may be combined in A, B, and C when described in “at least one (or more) of A (and), B, and C”. Further, in describing the elements of the embodiments of the present disclosure, the terms such as first, second, A, B, (a), and (b) may be used.

These terms are only used to distinguish the elements from other elements, and the terms are not limited to the essence, order, or order of the elements. In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements. Further, when expressed as “on (over)” or “under (below)”, it may include not only the upper direction but also the lower direction based on one element.

The terms used in the present application are used only to describe specific embodiments and are not intended to limit the present invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms used herein, including technical or scientific terms, have the same meaning as is generally understood by those of ordinary skill in the art to which the present invention pertains. Terms such as those defined in commonly used dictionaries should be interpreted as having meaning consistent with the meaning in the context of the relevant technology and are not interpreted in an ideal or overly formal sense unless explicitly defined in this application.

Hereinafter, embodiments will be described in detail with reference to the accompanying drawings. However, regardless of reference numerals, same or corresponding components are assigned with same reference numerals, and redundant descriptions thereof will be omitted.

Before describing the embodiment, an electronic device to which the semiconductor package of the embodiment is applied will be briefly described. The electronic device may be a smart phone, a personal digital assistant, a digital video camera, a digital still camera, a vehicle, a high-performance server, a network system, a computer, a monitor, a tablet, a laptop, a netbook, a television, a video game, a smart watch, an automotive, or the like. However, the embodiment is not limited thereto, and may be any other electronic device that processes data in addition to these.

The electronic device includes a main board (not shown). The main board may be physically and/or electrically connected to various components. For example, the main board may be connected to the semiconductor package of the embodiment. In addition, the semiconductor package includes a circuit board, a semiconductor chip, a bonding part that electrically connects semiconductor devices to circuit boards, a resin part filling a space between semiconductor devices and circuit boards, and a molding part covering the semiconductor devices as a whole.

The semiconductor device may include an active device and/or a passive device and may have various functions. The active device may be in a form of an integrated circuit (IC) in which hundreds to millions of transistors are integrated in one semiconductor device, and may be, for example, a logic chip or a memory chip. For example, the logic chip may be an application processor (AP) device including at least one of a central processor (CPU), a graphic processor (GPU), a digital signal processor, an encryption processor, a microprocessor, a microprocessor, or a microcontroller, or may be a device set including a specific combination of those listed so far. The memory chip may be a stack memory such as an HBM. In addition, the memory chip may include a memory chip such as a volatile memory (e.g., DRAM), a non-volatile memory (e.g., ROM), or a flash memory.

The semiconductor package of the embodiment may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

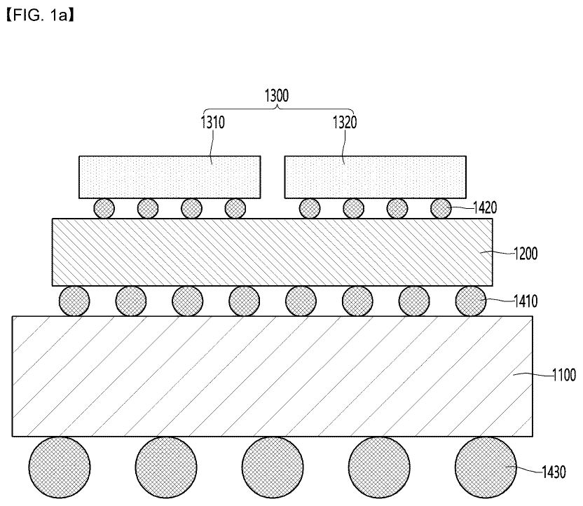

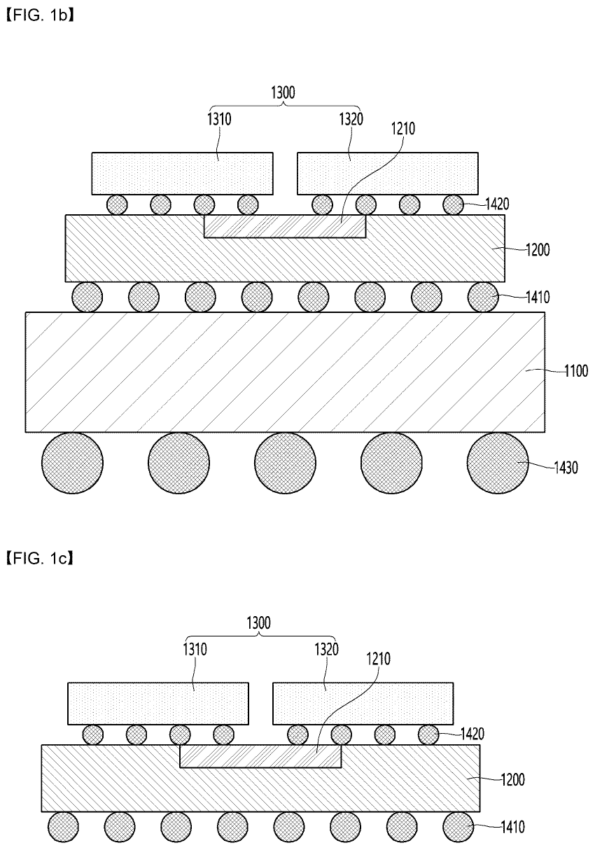

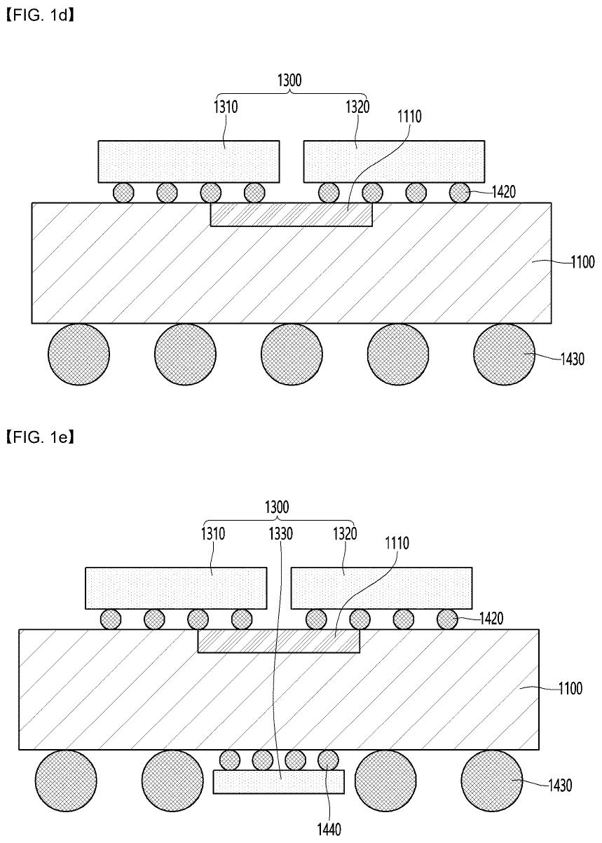

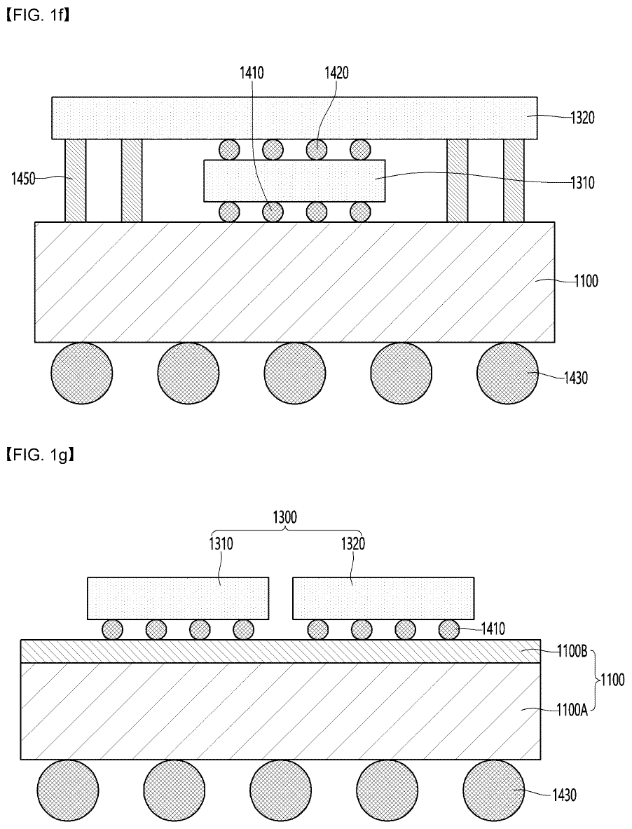

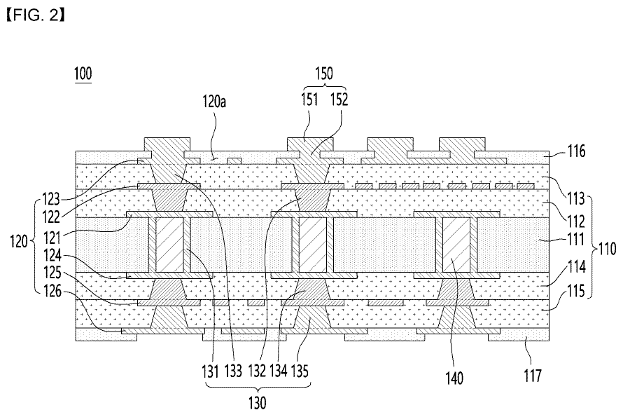

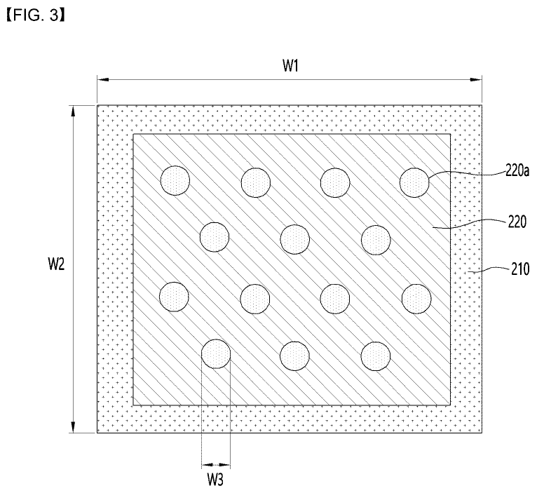

Hereinafter, a semiconductor package including a circuit board according to an embodiment will be described. A semiconductor package according to an embodiment may have various types of package structures including a circuit board which will be described later. Also, the circuit board described in an embodiment may be any one of a first circuit board and a second circuit board shown in any one of FIGS. 1a to 1g.

FIG. 1a is a cross-sectional view showing a semiconductor package according to a first embodiment, FIG. 1b is a cross-sectional view showing a semiconductor package according to a second embodiment, FIG. 1c is a cross-sectional view showing a semiconductor package according to a third embodiment, FIG. 1d is a cross-sectional view showing a semiconductor package according to a fourth embodiment, FIG. 1e is a cross-sectional view showing a semiconductor package according to a fifth embodiment, FIG. 1f is a cross-sectional view showing a semiconductor package according to a sixth embodiment, and FIG. 1g is a cross-sectional view showing a semiconductor package according to a seventh embodiment.

Referring to FIG. 1a, the semiconductor package according to the first embodiment may include a first circuit board 1100, a second circuit board 1200, and a semiconductor device 1300.

The first circuit board 1100 means a semiconductor package substrate. For example, the first circuit board 1100 may provide a space to which at least one external circuit board is coupled. The external circuit board may refer to a second circuit board 1200 coupled to the first circuit board 1100. Also, the external circuit board may refer to a main board included in an electronic device coupled to a lower portion of the first circuit board 1100.

Also, although not shown in the drawing, the first circuit board 1100 may provide a space in which at least one semiconductor device is mounted.

The first circuit board 1100 includes at least one insulating layer, a circuit layer disposed on the at least one insulating layer, and a through electrode passing through the at least one insulating layer.

A second circuit board 1200 is disposed on the first circuit board 1100. The second circuit board 1200 may be an interposer. For example, the second circuit board 1200 may provide a space in which at least one semiconductor device is mounted. The second circuit board 1200 may be connected to the at least one semiconductor device 1300. For example, the second circuit board 1200 may provide a space in which the first semiconductor device 1310 and the second semiconductor device 1320 are mounted. The second circuit board 1200 may electrically connect the first and second semiconductor devices 1310 and 1320 and the first circuit board 1100 while electrically connecting the first semiconductor device 1310 and the second semiconductor device 1320. That is, the second circuit board 1200 may perform a horizontal connection function between a plurality of semiconductor devices and a vertical connection function between the semiconductor devices and a package circuit substrate.

FIG. 1a illustrates that the first and second semiconductor devices 1310 and 1320 are disposed on the second circuit board 1200, but is not limited thereto. For example, one semiconductor device may be disposed on the second circuit board 1200, or alternatively, three or more semiconductor devices may be disposed.

The second circuit board 1200 may be disposed between at least one semiconductor device 1300 and the first circuit board 1100. In an embodiment, the second circuit board 1200 may be an active interposer that functions as a semiconductor device. When the second circuit board 1200 functions as a semiconductor device, the semiconductor package of the embodiment may have a structure that is vertically stacked on the first circuit board 1100 and may have functions of multiple logic chips. Having the function of a logic chip may mean that it may have functions of an active device and a passive device. In a case of an active device, characteristics of current and voltage may not be linear unlike a passive device, and in a case of an active interposer, it may have the function of an active device. In addition, the active interposer may perform a function of a corresponding logic chip while performing a signal transmission function between a second logic chip disposed thereon and the first circuit board 1100. The second circuit board 1200 according to another embodiment may be a passive interposer. For example, the second circuit board 1200 may perform a signal relay function between the semiconductor device 1300 and the first circuit board 1100, and may have a passive device function such as a resistor, a capacitor, an inductor, and the like. For example, a number of terminals of the semiconductor device 1300 is gradually increasing due to 5G, Internet of Things (IoT), image quality increase, communication speed increase, and the like. That is, the number of terminals provided in the semiconductor device 1300 is increasing, and thus a width of the terminals or a spacing between a plurality of terminals is decreasing. In this case, the first circuit board 1100 may be connected to a main board of the electronic device. Accordingly, in order to have a width and a spacing for connecting electrodes provided on the first circuit board 1100 to the semiconductor device 1300 and the main board, respectively, there is a problem in that a thickness of the first circuit board 1100 is increased or a layer structure of the first circuit board 1100 is complicated. Accordingly, in the first embodiment, the second circuit board 1200 may be disposed on the first circuit board 1100 and the semiconductor device 1300. In addition, the second circuit board 1200 may include an electrode having a fine width and a spacing corresponding to the terminal of the semiconductor device 1300.

A first connecting part 1410 is disposed between a first circuit board 1100 and a second circuit board 1200. The first connecting part 1410 electrically connects the first circuit board 1100 and the second circuit board 1200 while bonding the second circuit board 1200 to the first circuit board 1100. A second connecting part 1420 is disposed between the second circuit board 1200 and the semiconductor device 1300. The second connecting part 1420 may electrically connect the semiconductor device 1300 and the second circuit board 1200 while bonding the semiconductor device 1300 to the second circuit board 1200. A third connecting part 1430 disposed on a lower surface of the first circuit board 1100. The third connecting part 1430 may electrically connect the first circuit board 1100 and the main board while bonding the first circuit board 1100 to the main board.

At this time, the first connecting part 1410, the second connecting part 1420, and the third connecting part 1430 may electrically connect between the plurality of components by using at least one bonding method of wire bonding, solder bonding and metal-to-metal direct bonding. That is, since the first connecting part 1410, the second connecting part 1420, and the third connecting part 1430 have a function of electrically connecting a plurality of components, when the metal-to-metal direct bonding is used, the connecting part of the semiconductor package may be understood as an electrically connected portion, not a solder or wire.

The wire bonding method may refer to electrically connecting a plurality of components using a conductive wire such as gold (Au). Also, the solder bonding method may electrically connect a plurality of components using a material containing at least one of Sn, Ag, and Cu. In addition, the metal-to-metal direct bonding method may refer to recrystallization by applying heat and pressure between a plurality of components without the presence of solder, wire, conductive adhesive, etc. In addition, to directly bond between the plurality of components. In addition, the metal-to-metal direct bonding method may refer to a bonding method by the second connecting part 1420. In this case, the second connecting part 1420 may mean a metal layer formed between a plurality of components by the recrystallization.

The first connecting part 1410, the second connecting part 1420, and the third connecting part 1430 may couple a plurality of components to each other by a thermal compression (TC) bonding method. The thermal compression bonding may refer to a method of directly bonding a plurality of components by applying heat and pressure to the first connecting part 1410, the second connecting part 1420, and the third connecting part 1430.

In this case, at least one of the first circuit board 1100 and the second circuit board 1200 may include a protrusion provided in the electrode on which the first connecting part 1410, the second connecting part 1420, and the third connecting part 1430 are disposed. The protrusion may protrude outward from the first circuit board 1100 or the second circuit board 1200. The protrusion may be referred to as a bump, or a post, or a pillar. Preferably, the protrusion may refer to an electrode on which a second connecting part 1420 for bonding with the semiconductor device 1300 is disposed among the electrodes of the second circuit board 1200. That is, as the pitch of the terminals of the semiconductor device 1300 becomes finer, a short circuit may occur between the plurality of second connecting parts 1420 that are respectively connected to the plurality of terminals of the semiconductor device 1300 by a conductive adhesive such as a solder. Therefore, in the embodiment, thermal compression bonding may be performed to reduce a volume of the second connecting part 1420. In addition, in order to secure diffusion prevention and alignment to prevent an intermetallic compound (IMC) formed between a conductive adhesive such as solder and a protrusion from diffusing into the interposer and/or the circuit board, a protrusion may be included in the electrode of the second circuit board 1200 on which the second connecting part 1420 is disposed.

Meanwhile, referring to FIG. 1b, the semiconductor package of the second embodiment is different from the semiconductor package of the first embodiment in that the connection member 1210 is disposed on the second circuit board 1200. The connection member 1210 may be referred to as a bridge. For example, the connection member 1210 may include a redistribution layer. The connection member 1210 may perform a function of electrically connecting a plurality of semiconductor devices horizontally to each other. For example, since the area that a semiconductor device should generally have been too large, the connection member 1210 may include a redistribution layer. Since the semiconductor package and the semiconductor device have a large difference in a width or spacing of the circuit pattern, etc., a buffering role of the circuit pattern for electrical connection is required. The buffering role may mean having a size between a width or spacing of the circuit pattern of the semiconductor package and a width or spacing of the circuit pattern of the semiconductor device, and the redistribution layer may include a function of performing the buffering role. In an embodiment, the connection member 1210 may be a silicon bridge. That is, the connection member 1210 may include a silicon substrate and a redistribution layer disposed on the silicon substrate. In another embodiment, the connection member 1210 may be an organic bridge. For example, the connection member 1210 may include an organic material. For example, the connection member 1210 may include an organic substrate including an organic material instead of a silicon substrate. Particularly, when the connection member 1210 includes an organic material, a structure of the circuit board according to an embodiment described below may more stably protect the connection member 1210 from a stress caused by a heat cycle such as contraction and/or expansion of the semiconductor package. The connection member 1210 may be an organic bridge capable of smoothly supplying power from a lower side to an upper side and minimizing a loss of supplied power. In this case, in a case of an inorganic bridge including a silicon substrate, power may be supplied through a through-silicon via (TSV), but there are problems in that a process cost for TSV processing increases and a product yield decreases. Accordingly, it is preferable that the connection member 1210 according to an embodiment is an organic bridge.

The connection member 1210 may be embedded in the second circuit board 1200, but is not limited thereto. For example, the connection member 1210 may be disposed on the second circuit board 1200 to have a protruding structure. In addition, the second circuit board 1200 may include a cavity, and the connection member 1210 may be disposed in the cavity of the second circuit board 1200. The connection member 1210 may horizontally connect a plurality of semiconductor devices disposed on the second circuit board 1200.

Referring to FIG. 1c, the semiconductor package according to the third embodiment may include a second circuit board 1200 and a semiconductor device 1300. In this case, the semiconductor package of the third embodiment may have a structure in which the first circuit board 1100 is removed compared to the semiconductor package of the second embodiment.

That is, the second circuit board 1200 of the third embodiment may function as a semiconductor package substrate while performing an interposer function. The first connecting part 1410 disposed on the lower surface of the second circuit board 1200 may couple the second circuit board 1200 to the main board of the electronic device.

Referring to FIG. 1d, the semiconductor package according to the fourth embodiment may include a first circuit board 1100 and a semiconductor device 1300. In this case, the semiconductor package of the fourth embodiment may have a structure in which the second circuit board 1200 is removed compared to the semiconductor package of the second embodiment. That is, the first circuit board 1100 of the fourth embodiment can function as a package circuit board while also performing the function of connecting the semiconductor device 1300 and a main board. To this end, the first circuit board 1100 may include a connection member 11 for connecting the plurality of semiconductor devices. The connection member 11 may be a silicon bridge or an organic material bridge connecting a plurality of semiconductor devices.

Referring to FIG. 1e, the semiconductor package of the fifth embodiment may further include a third semiconductor device 1330 compared to the semiconductor package of the fourth embodiment. To this end, a fourth connecting part 1440 may be disposed on the lower surface of the first circuit board 1100. In addition, a third semiconductor device 33 may be disposed on the fourth connecting part 1440. That is, the semiconductor package of the fifth embodiment may have a structure in which semiconductor devices are mounted on upper and lower sides, respectively. In this case, the third semiconductor device 1330 may have a structure disposed on the lower surface of the second circuit board 1200 in the semiconductor package of FIG. 1c.

Referring to FIG. 1f, the semiconductor package according to the sixth embodiment may include a first circuit board 1100. A first semiconductor device 1310 may be disposed on the first circuit board 1100. To this end, a first connecting part 1410 may be disposed between the first circuit board 1100 and the first semiconductor device 1310. In addition, the first circuit board 1100 includes a conductive bonding portion 1450. The conductive bonding portion 1450 may further protrude from the first circuit board 1100 toward the second semiconductor device 1320. The conductive bonding portion 1450 may be referred to as a bump or, alternatively, may also be referred to as a post. The conductive bonding portion 1450 may be disposed to have a protruding structure on an electrode disposed at an uppermost side of the first circuit board 1100. A second semiconductor device 1320 may be disposed on the conductive bonding portion 1450. In this case, the second semiconductor device 1320 may be connected to the first circuit board 1100 through the conductive bonding portion 1450. In addition, a second connecting part 1420 may be disposed on the first semiconductor device 1310 and the second semiconductor device 1320. Accordingly, the second semiconductor device 1320 may be electrically connected to the first semiconductor device 1310 through the second connecting part 1420.

That is, the second semiconductor device 1320 may be connected to the first circuit board 1100 through the conductive bonding portion 1450, and may be also connected to the first semiconductor device 1310 through the second connecting part 1420. In this case, the second semiconductor device 1320 may receive a power signal and/or electric power through the conductive bonding portion 1450. Also, the second semiconductor device 1320 may transmit and receive a communication signal to and from the first semiconductor device 1310 through the second connecting part 1420. The semiconductor package according to the sixth embodiment provides a power signal and/or electric power to the second semiconductor device 1320 through the conductive bonding portion 1450, thereby providing sufficient power for driving the second semiconductor device 1320 or enabling smooth control of a power operation. Accordingly, the embodiment may improve the driving characteristics of the second semiconductor device 1320. That is, the embodiment may solve a problem of insufficient power provided to the second semiconductor device 1320. Furthermore, in the embodiment, at least one of a power signal, an electric power, and a communication signal of the second semiconductor device 1320 are provided through different paths through the conductive bonding portion 1450 and the second connecting part 1420. Through this, the embodiment can solve the problem that the communication signal is lost due to the power signal. For example, the embodiment may minimize mutual interference between communication signals of power signals.

Meanwhile, the second semiconductor device 1320 in the sixth embodiment may have a POP (Package On Package) structure in which a plurality of semiconductor package substrates are stacked and may be disposed on the first circuit board 1100. For example, the second semiconductor device 1320 may be a memory package including a memory chip. In addition, the memory package may be coupled on the conductive bonding portion 1450. In this case, the memory package may not be connected to the first semiconductor device 1310.

Referring to FIG. 1g, the semiconductor package according to the seventh embodiment may include a first circuit board 1100, a first connecting part 1410, a first connecting part 1410, a semiconductor device 1300, and a third connecting part 1430.

In this case, the semiconductor package of the seventh embodiment is different from the semiconductor package of the fourth embodiment in that the first circuit board 1100 includes a plurality of substrate layers while the connection member 1110 is removed.

The first circuit board 1100 includes a plurality of circuit board layers. For example, the first circuit board 1100 may include a first substrate layer 1100A corresponding to a package substrate and a second substrate layer 1100B corresponding to a redistribution layer of the connection member. For example, the semiconductor package of the seventh embodiment may include a first substrate layer 1100A and a second substrate layer 1100B in which the first circuit board (semiconductor package substrate, 1100) and the second circuit board (interposer, 1200) disclosed in FIG. 1a are integrally formed. A material of the insulating layer of the second substrate layer 1100B may be different from a material of an insulating layer of the first substrate layer 1100A. For example, the material of an insulating layer of the second substrate layer 1100B may include a photocurable material. For example, the second substrate layer 1100B may be a photo imageable dielectric (PID). In addition, since the second substrate layer 1100B includes a photocurable material, it is possible to miniaturize the electrode. Accordingly, in the seventh embodiment, the second substrate layer 1100B may be formed by sequentially stacking an insulating layer of a photo-curable material on the first substrate layer 1100A and forming a miniaturized electrode on the insulating layer of the photo-curable material. Accordingly, the second substrate layer 1100B may include a redistribution layer function including a micro-electrode and may include a function of horizontally connecting a plurality of semiconductor devices 1310 and 1320.

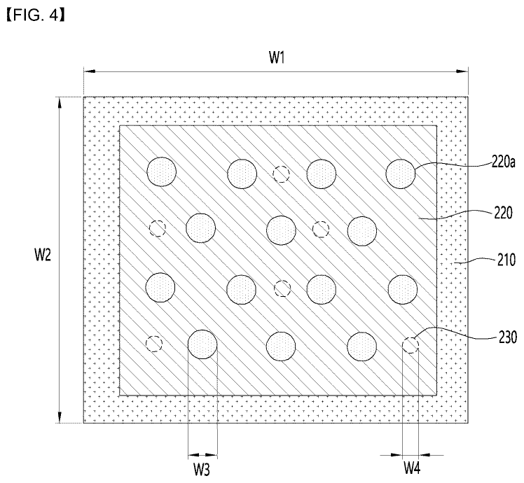

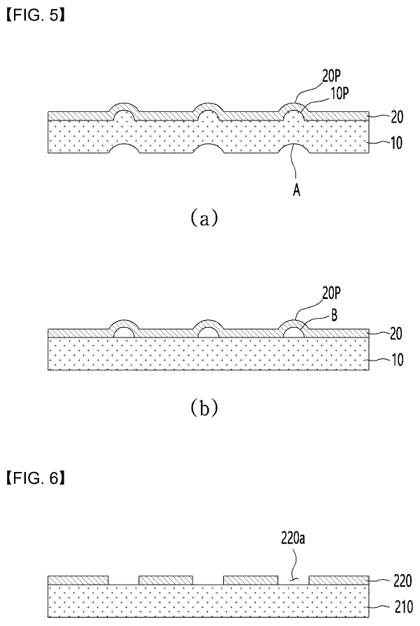

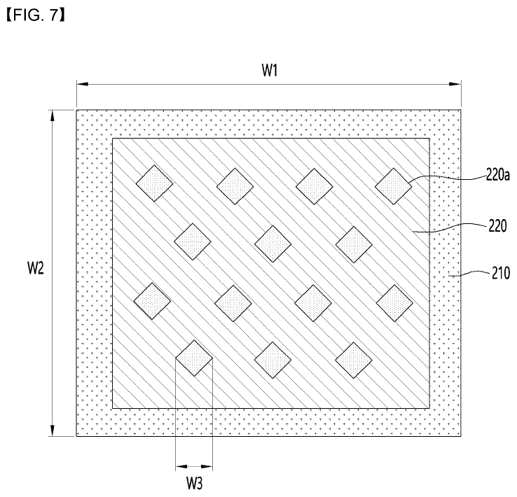

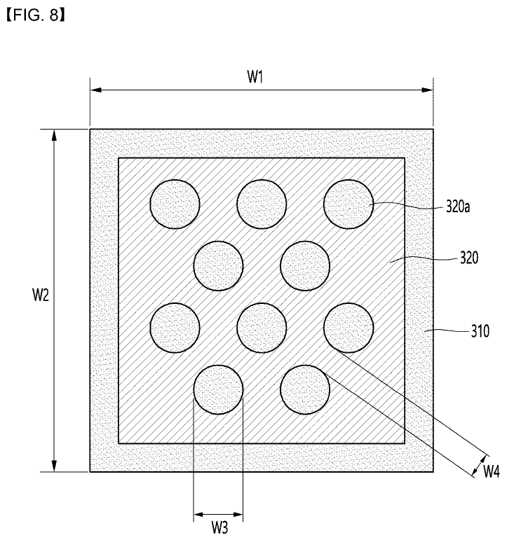

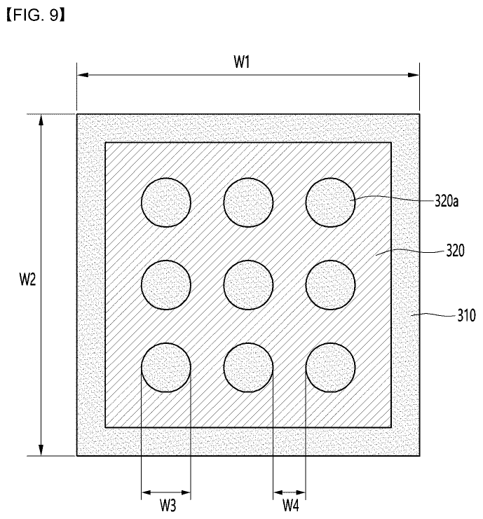

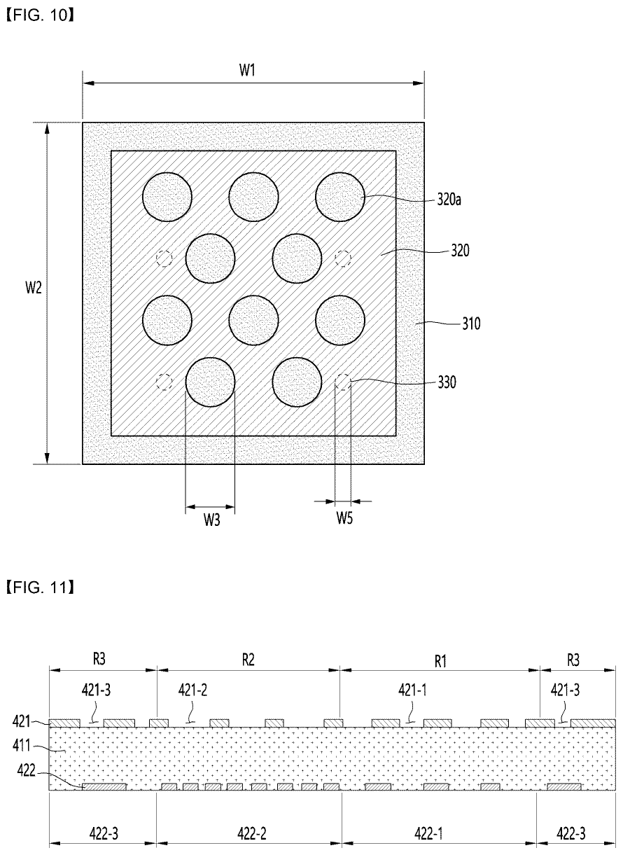

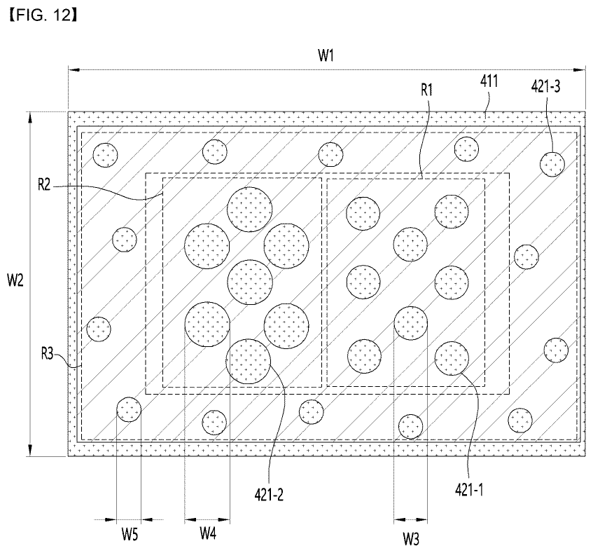

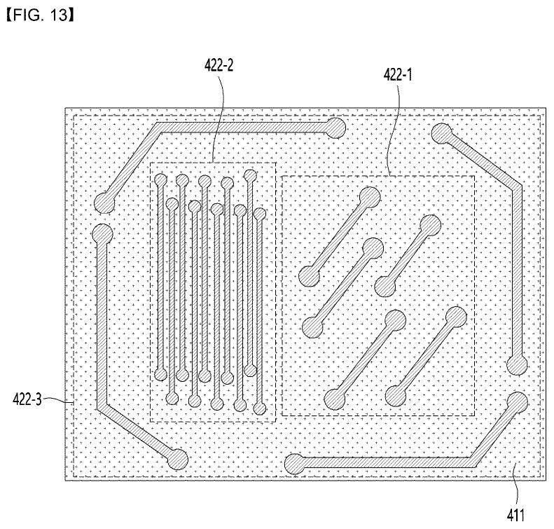

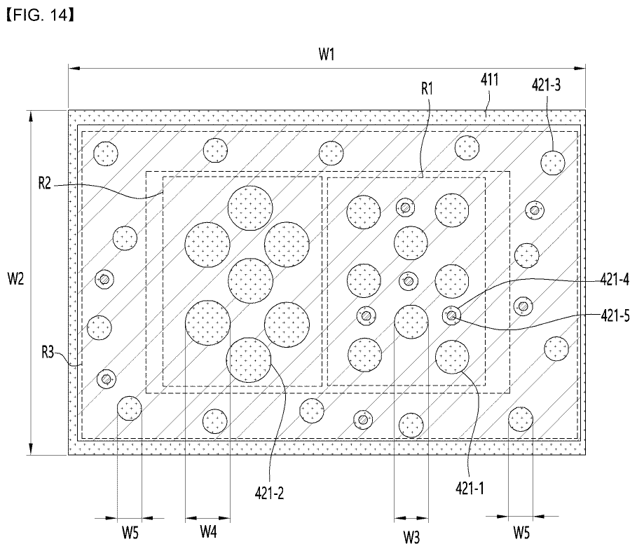

FIG. 2 is a cross-sectional view illustrating a circuit board according to a first embodiment, FIG. 3 is a plan view illustrating some layers of the circuit board of FIG. 2, FIG. 4 is a plan view for explaining a relationship between a through electrode and a through hole in a plan view of FIG. 3, FIGS. 5 and 6 are diagrams for explaining adhesion characteristics of circuit boards of the comparative example and the first embodiment, FIG. 7 is a plan view for explaining a modified example of the circuit board of FIG. 3, FIG. 8 is a plan view illustrating some layers of the circuit board of FIG. 2 according to a second embodiment, FIG. 9 is a plan view illustrating some layers of the circuit board of FIG. 2 according to a third embodiment, FIG. 10 is a plan view for explaining a relationship between a through electrode and a through hole in a plan view of FIG. 8, FIG. 11 is an enlarged view of some layers of the circuit board of FIG. 2 according to a fourth embodiment, FIG. 12 is a plan view for explaining diameters of a plurality of through holes provided in a first circuit layer of FIG. 11, FIG. 13 is a plan view for explaining a wiring density of a second circuit layer of FIG. 11, and FIG. 14 is a plan view for explaining a relationship between a through electrode and a through hole in a plan view of FIG. 12.

Hereinafter, a circuit board according to an embodiment will be described in detail with reference to FIGS. 2 to 14. Hereinafter, embodiments will be described in detail with reference to the accompanying drawings. However, regardless of reference numerals, same or corresponding components are assigned with same reference numerals, and redundant descriptions thereof will be omitted.

Referring to FIG. 2, a circuit board 100 according to an embodiment may include an insulating substrate 110, a first protective layer 116, a second protective layer 117, a circuit layer 120, a through electrode 130, an insulating member 140, and a bonding part 150.

The insulating substrate 110 may be provided with a plurality of layers. For example, the insulating substrate 110 may include a core layer 111, an upper build-up insulating layer 112 and 113 disposed on one surface of the core layer, and a lower build-up insulating layer 114 and 115 disposed on another surface of the core layer 111. In addition, each of the upper build-up layer 112 and 113 and the lower build-up layer 114 and 115 may be provided as a single layer, or may have a structure in which a plurality of layers are laminated along a vertical direction. The core layer 111 is composed of a resin such as epoxy resin or BT (bismaleimide triazine) and a reinforcing material such as glass fiber, and has a function of improving the rigidity of the circuit board 100. Recently, as the number of terminals of semiconductor devices disposed on a circuit board 100 increases, wiring becomes more complex, and accordingly, a thickness of the circuit board 100 is increasing. Accordingly, the core layer 110 of the present embodiment may have a thickness of 400 μm to 1200 μm in order to improve the overall rigidity of the circuit board 100 and prevent excessive signal loss. A via hole passing through one surface and the other surface may be formed in the core layer 111. The via hole of the core layer 111 may be formed using a mechanical drilling process or a CO₂ laser, etc. When a via hole of the core layer 111 is formed using a mechanical drill, an inclination of an inner wall of the via hole may be perpendicular to one surface and/or the other surface of the core layer 111, and when the via hole of the core layer 111 is formed using a CO₂ laser, an inner wall of the via hole may have a plurality of concave portions and/or convex portions alternately laminated along the vertical direction. Here, the concave portion may mean a concave region that is concave in a direction away from a center in a horizontal direction of the via hole provided in the core layer 111, and the convex portion may mean a region that protrudes and/or is convex toward a center in the horizontal direction of the via hole provided in the core layer 111. In the case of a via hole formed using a mechanical drilling process, a path for transmitting an electrical signal may be shortened, which may be advantageous for electrical characteristics, but a process cost may increase. In addition, when forming the concave portion and the convex portion on the inner wall of the via hole using a CO₂ laser, a thickness of a core through electrode 131 provided on the inner wall of the via hole of the core layer 111 can be thickened in a subsequent process, which can have the advantage of lowering the impedance and lowering the process cost. Accordingly, a processing method of the via hole provided in the core layer 111 can be freely and selectively used depending on an application field of the semiconductor package.

A core through electrode 131 can be disposed in the via hole of the core layer 111. The core through electrode 131 has a function of electrically connecting a circuit layer provided in the upper build-up insulating layer 112 and 113 and a circuit layer provided in the lower build-up insulating layer 114 and 115. Therefore, it is desirable for the core through electrode 131 to densely fill the via hole for the function of resistance or heat dissipation. However, when a thickness of the core layer 111 becomes thick as described above, it may become difficult to densely fill the via hole with the core through electrode 131. For example, when attempting to fill the via hole provided in the thick core layer 111 as described above according to the plating process, a void may occur inside the core through electrode 131. The void expands due to heat generated during the operation of the semiconductor package, which is a factor that deteriorates the mechanical reliability of the circuit board. Therefore, the core through electrode 131 having a predetermined thickness is disposed on the inner wall of the via hole of the core layer 111. The thickness of the core through electrode 131 refers to a thickness in the horizontal direction perpendicular to the vertical direction, not the thickness in a vertical direction in which the upper build-up insulating layer 112 and 113, the core layer 111, and the lower build-up insulating layer 114 and 115 are laminated. The thickness of the core through electrode 131 can be disposed to have a thickness of 5 μm to 20 μm to prevent a voltage drop and to prevent the occurrence of voids that occurs as the thickness of the core layer 111 increases. The inside of the core through electrode 131 is difficult to densely fill the metal through a process such as plating, thereby generating an empty space. The empty space can cause a problem in that it is difficult to evenly arrange the upper build-up insulating layers 112 and 113, the circuit layer 120, and the lower build-up insulating layers 114 and 115.

Therefore, an insulating member 140 can be disposed on the inner side of the core through electrode 131, thereby ensuring a flatness of the core layer 111. An upper surface of the insulating member 140 may be on a same plane as an upper surface of the core layer 111, or may be disposed closer to the upper build-up insulating layer 112 and 113 along the vertical direction than the upper surface of the core layer 111. A lower surface of the insulating member 140 may be on a same plane as a lower surface of the core layer 111, or may be disposed closer to the lower build-up insulating layer 114 and 115 along the vertical direction than the lower surface of the core layer 111. This may be freely designed to solve the flatness when laminating the upper build-up insulating layer 112 and 113, the lower build-up insulating layer 114 and 115, and the circuit layer 120, or to secure the flatness of the first circuit layer 121 and/or the fourth circuit layer 124 to be described later.

An upper build-up insulating layer 112 and 113, a plurality of circuit layers 121, 122, and 123, a plurality of through electrodes 132 and 133, and a first protective layer 116 may be disposed on one surface of the core layer 111.

The plurality of circuit layers 121, 122, and 123 disposed on one surface of the core layer 111 may include a first circuit layer 121 closest to the core layer 111 in the vertical direction, a second circuit layer 122 farther to the core layer 111 in the vertical direction than the first circuit layer 121, and a third circuit layer 123 farther to the core layer 111 in the vertical direction than the second circuit layer 122.

The first to third circuit layers 121, 122, and 123 may have a function of electrically connecting to a semiconductor device disposed on a circuit board 100. Each of the first to third circuit layers 121, 122, and 123 can be freely designed in consideration of impedance. In addition, a through electrode 132 and 133 can be disposed to connect each of the first to third circuit layers 121, 122, and 123. For example, a first through electrode 132 is disposed between the first circuit layer 121 and the second circuit layer 122, and a second through electrode 133 is disposed between the second circuit layer 122 and the third circuit layer 123, thereby electrically connecting the first to third circuit layers 121, 122, and 123. The first to third circuit layers 121, 122, and 123 can include at least one through hole. For example, the third circuit layer 123 may be provided with a through hole 120a passing through upper and lower surfaces of the third circuit layer 123. The through hole 120a provided in the first to third circuit layers 121, 122, and 123 may have a different meaning from a separation region between the plurality of circuit patterns of each of the first to third circuit layers 121, 122, and 123. Specifically, the separation region may be connected to an outer surface of each circuit pattern and may be provided between outer surfaces of the plurality of circuit patterns. In contrast, the through hole 120a may be provided passing through upper and lower surfaces of each circuit pattern and may not be connected to the outer surface of each circuit pattern. Through this, the through hole 120a and the separation region may be distinguished. For example, each of the first to third circuit layers 121, 122, and 123 may have a plurality of pads and a plurality of traces connecting the plurality of pads. In addition, the through hole 120a may have a different meaning from a separation region between the plurality of pads, a separation region between the pads and the traces, and a separation region between the plurality of traces. The through hole 120a may allow gas generated during curing of the first and second insulating layers 112 and 113 to be easily exhausted. This will be described later.

The first and second through electrodes 132 and 133 can be simultaneously performed in a process of arranging the second and third circuit layers 122 and 123. For example, in a process of arranging the second circuit layer 122 on the first circuit layer 121, a through hole can be formed in the first insulating layer 112 of the upper build-up insulating layer to expose a part of the first circuit layer 121, and the second circuit layer 122 can be disposed together with the first through electrode 132 filling the through hole of the first insulating layer 112 of the upper build-up insulating layer. Accordingly, the first through electrode 132 can be distinguished by a protrusion of the second circuit layer 122. Similarly, the second through electrode 133 can be distinguished by a protrusion of the third circuit layer 123 and connected to another circuit layer disposed below a corresponding circuit layer.

The first circuit layer 121 may be in contact with one surface of the core layer 111. In this case, a part of the first circuit layer 121 may be disposed to cover the insulating member 140 described above. A part of the first circuit layer 121 covering the insulating member 140 may be thinner than a remaining part that do not vertically overlap with the insulating member 140. Here, a thickness of the first circuit layer 121 refers to a thickness along the vertical direction. When designing the first circuit layer 121, the insulating member 140 may be covered or not covered depending on a degree of freedom of wiring, and thus the degree of freedom of wiring connection may be increased. When the first circuit layer 121 does not cover the insulating member 140, the insulating member 140 may be in direct contact with a first insulating layer 112 of the upper build-up insulating layer. When the first circuit layer 121 and the first insulating layer 112 of the upper build-up insulating layer are in contact with each other, a bonding strength may be better and heat dissipation may be advantageous compared to when the insulating member 140 and the first insulating layer 112 of the upper build-up insulating layer are in direct contact. However, in order to reduce the process cost, the first circuit layer 121 may be disposed so as not to cover the insulating member 140. Furthermore, depending on the design of the first through electrode 132, the first circuit layer 121 may or may not cover the insulating member 140. For example, when the first through electrode 132 is disposed to overlap the first circuit layer 121 in a vertical direction, the first circuit layer 121 may be provided to cover the insulating member 140 in order to secure electrical connectivity and/or mechanical coupling between the first circuit layer 121 and the first through electrode 132. In addition, if the first through electrode 132 overlapping the first circuit layer 121 in the vertical direction is not disposed, the first circuit layer 121 may be provided without covering the insulating member 140.

The upper build-up insulating layer 112 and 113 may have a structure in which a plurality of layers are laminated along the vertical direction. The upper build-up insulating layer 112 and 113 may include a first insulating layer 112 closest to the core layer 111 in the vertical direction from the core layer 111 and a second insulating layer 113 farther from the core layer 111 in the vertical direction than the first insulating layer 112.

The first and second insulating layers 112 and 113 are disposed for vertical insulation between the first to third circuit layers 121, 122, and 123 described above. For example, the first and second insulating layers 112 and 113 may be formed using a thermosetting insulating material containing an inorganic filler contained in a resin, and Ajinomoto Build-up Film (ABF) from Ajinomoto Co., Ltd. may be used. However, the embodiment is not limited thereto, and a photo-curable insulating material (Photo Imageable Dielectric, PID) for forming a fine pattern may be used.

The first protective layer 116 may protect the third circuit layer 123 from external moisture or contaminants. In addition, when a semiconductor device is disposed on a circuit board 100 using a material such as solder, the first protective layer 116 functions to prevent short circuits between solders due to low wettability with the solder. The first protective layer 116 may be formed using a photo-curable insulating material, and for example, a solder resist may be used.

A lower build-up insulating layer 114 and 115, a plurality of circuit layers 124, 125, and 126, a plurality of through electrodes 134 and 135, and a second protective layer 117 may be disposed on the other surface of the core layer 111.

The plurality of circuit layers 124, 125, and 126 disposed on the other surface of the core layer 111 may include a fourth circuit layer 124 closest to the core layer 111 in the vertical direction, a fifth circuit layer 125 farther to the core layer 111 in the vertical direction than the fourth circuit layer 124, and a sixth circuit layer 126 farther to the core layer 111 in the vertical direction than the fifth circuit layer 125.

The fourth to sixth circuit layers 124, 125, and 126 may electrically connect a main board (not shown) of an electronic device and a semiconductor device disposed on a circuit board 100. Each of the fourth to sixth circuit layers 124, 125, and 126 may be freely designed in consideration of impedance. The fourth to sixth circuit layers 124, 125, and 126 may have at least one through hole. In addition, similar to the through hole 120a provided in the first to third circuit layers 121, 122, and 123 described above, the through hole provided in the fourth to sixth circuit layers 124, 125, and 126 may have a different meaning from a separation region between the plurality of circuit patterns of each of the fourth to sixth circuit layers 124, 125, and 126. For example, each of the fourth to sixth circuit layers 124, 125, and 126 may have a plurality of pads and a plurality of traces connecting the plurality of pads. In addition, the through holes provided in the fourth to sixth circuit layers 124, 125, and 126 may have different meanings from a spacing between the plurality of pads, a spacing between the pads and the traces, and a spacing between the plurality of traces of each of the fourth to sixth circuit layers 124, 125, and 126. The through holes provided in the fourth to sixth circuit layers 124, 125, and 126 may allow gas generated during curing of the third and fourth insulating layers 114 and 115 to be easily discharged. This will be described later.

In addition, a through electrode 134 and 135 may be disposed to connect each of the fourth to sixth circuit layers 124, 125, and 126. For example, a third through electrode 134 is disposed between the fourth circuit layer 124 and the fifth circuit layer 125, and a fourth through electrode 135 is disposed between the fifth circuit layer 125 and the sixth circuit layer 126, thereby electrically connecting the fourth to sixth circuit layers 124, 125, and 126.

As described above with respect to the first and second through electrodes 132 and 133, the third and fourth through electrodes 134 and 135 can also be performed simultaneously in a process of arranging the fifth and sixth circuit layers 125 and 126. For example, as described above, the third through electrode 134 can be distinguished by a protrusion of the fifth circuit layer 125. In addition, the fourth through electrode 135 can be distinguished by a protrusion of the sixth circuit layer 126. The layers disposed at an upper side of the core layer 111 and the layers disposed at a lower side of the core layer 111 are laminated in different directions, and an inclination direction of the third and fourth through electrodes 134 and 135 may have a direction opposite to an inclination direction of the first and second through electrodes 132 and 133. For example, the first and second through electrodes 132 and 133 may have an inclination that becomes narrower as the first and second through electrodes 132 and 133 approach the core layer 111, and the third and fourth through electrodes 134 and 135 may also have an inclination that becomes narrower as the third and fourth through electrodes 134 and 135 approach the core layer 111. The inclination of the first and second through electrodes 132 and 133 may be symmetrical to the inclination of the third and fourth through electrodes 134 and 135 with respect to the core layer 111.

The fourth circuit layer 124 may be in contact with the other surface of the core layer 111. In this case, a part of the fourth circuit layer 124 may be disposed to cover the insulating member 140 described above. A part of the fourth circuit layer 124 covering the insulating member 140 may be thinner than a remaining parts that do not vertically overlap with the insulating member 140. Here, a thickness of the fourth circuit layer 124 refers to a thickness along the vertical direction. When designing the fourth circuit layer 124, the insulating member 140 may be covered or not covered depending on the degree of freedom of wiring, and thus the degree of freedom of wiring connection may be increased. When the fourth circuit layer 124 does not cover the insulating member 140, the insulating member 140 may be in direct contact with the third insulating layer 114. Compared to a case where the insulating member 140 and the third insulating layer 114 are in direct contact, a case where the fourth circuit layer 124 and the third insulating layer 114 are in contact may have better bonding strength and may be advantageous for heat dissipation. However, in order to reduce the process cost, the fourth circuit layer 124 may be disposed so as not to cover the insulating member 140. In addition, depending on the design of the third through electrode 134, the fourth circuit layer 124 may or may not cover the insulating member 140. For example, when the third through electrode 134 is disposed to vertically overlap the fourth circuit layer 124, the fourth circuit layer 124 may be provided to cover the insulating member 140 in order to secure electrical connectivity and/or mechanical coupling between the fourth circuit layer 124 and the third through electrode 134. In addition, when the third through electrode 134 overlapping the fourth circuit layer 124 in the vertical direction is not disposed, the fourth circuit layer 124 may be provided without covering the insulating member 140.

The lower build-up insulating layer 114 and 115 may have a structure in which a plurality of layers are laminated along the vertical direction. The lower build-up insulating layer 114 and 115 may include a third insulating layer 114 closest to the core layer 111 in the vertical direction, and a fourth insulating layer 115 farther from the core layer 111 in the vertical direction than the third insulating layer 114.

The third and fourth insulating layers 114 and 115 are disposed for vertical insulation between the fourth to sixth circuit layers 124, 125, and 126 described above. For example, the third and fourth insulating layers 114 and 115 may be formed using a thermosetting insulating material containing an inorganic filler in the resin, and Ajinomoto Build-up Film (ABF) from Ajinomoto Co., Ltd. may be used. However, the embodiment is not limited thereto, and a photo-curable insulating material (Photo Imageable Dielectric, PID) for forming a fine pattern may be used.

A second protective layer 117 may protect the sixth circuit layer 126 from external moisture or contaminants. In addition, when a semiconductor device is disposed on a circuit board 100 using a material such as solder, the second protective layer 117 functions to prevent short circuits between solders due to low wettability with the solder. The second protective layer 117 may be formed using a photo-curable insulating material, and for example, a solder resist may be used.

Some regions of the third circuit layer 123 may include a pad part exposed from the first protective layer 116. In addition, as the density of terminals of semiconductor devices increases, conventional solder bonding can cause a short circuit problem of solder between adjacent pad parts. Therefore, in order to reduce an amount of solder used as the density of terminals of the semiconductor device increases, the semiconductor device and the circuit board 100 may be bonded to each other through a thermal compression bonding method. When the thermal compression bonding is used, the circuit board 100 may include a bonding part 150 protruding on the first protective layer 116. The bonding part 150 may have a protrusion 151 protruding on the first protective layer 116 and a through part 152 passing through the first protective layer 116 and in contact with the third circuit layer 123. In addition, when bonding the circuit board 100 and the semiconductor device by the thermal compression bonding method, a crack may occur in the through part 152 of the bonding part 150 due to the load generated thereby. Therefore, the through part 152 of the bonding part 150 can prevent cracks by arranging a material having higher elasticity than the elasticity of the third circuit layer 123 in a portion adjacent to the third circuit layer 123. This material may be nickel (Ni), but a copper layer having a low grain density may be disposed by electroless plating. At this time, the protrusion 151 and the through part 152 of the bonding part 150 can be disposed in various ways. For example, a process may be performed in which the first protective layer 116 is exposed and developed to form an opening in the first protective layer 116, and then the protrusion 151 and the through part 152 of the bonding part 150 are disposed in the opening. In addition, a process may be performed in which an opening is formed in the first protective layer 116 using a laser, and then the protrusion 151 and the through part 152 of the bonding part 150 are disposed in the opening. In addition, by using DFR (Dry Film resist), DFR is first disposed in a region where the through part 152 is to be disposed, and then the first protective layer 116 is disposed so that the DFR is covered, and then a part of the first protective layer 116 is etched with a chemical solution to expose the DFR, and then the DFR is peeled off to form an opening in the first protective layer 116, and then the protrusion 151 and the through part 152 of the bonding part 150 can be disposed. Therefore, the through part 152 of the bonding part 150 can have various shapes depending on the process method. For example, when the opening of the first protective layer 116 is formed through an exposure process, a side surface of the through part 152 of the bonding part 150 may have a structure in which the width gradually narrows toward the third circuit layer 123, when the opening of the first protective layer 116 is formed through a laser process, the side surface of the through part 152 may have a vertical side surface and a curved side surface adjacent to the third circuit layer 123, and when the opening of the first protective layer 116 is formed using DFR, the side surface of the through part 152 may have only a vertical side surface. As described above, when the semiconductor device is bonded to the circuit board 100 through the thermal compression bonding, a load may be applied to the through part 152, and in a case of the through part 152 using DFR, the stress may be uniformly applied, thereby increasing the manufacturing yield.

A structure of the circuit board 100 described above is only an example for explaining the present invention, and a technical idea of the present invention is not limited to a laminated structure of the present embodiment.

In addition, it has been described that the third circuit layer 123 and the sixth circuit layer 126 disposed at the uppermost and lowermost sides of the circuit layers 120 of the circuit board 100 have a structure protruding from the upper surface of the second insulating layer 113 and the lower surface of the fourth insulating layer 115, but the embodiment is not limited thereto. For example, at least one circuit layer among the third circuit layer 123 and the sixth circuit layer 126 may have an ETS (Embedded Trace Substrate) structure. For example, the third circuit layer 123 may be disposed in a recess provided on the upper surface of the second insulating layer 113. The ETS structure described above may also be referred to as a buried structure. The ETS structure is advantageous for miniaturization compared to a circuit layer having a general protruding structure. Accordingly, the embodiment enables the formation of circuit layers corresponding to a size and a pitch of terminals provided in the semiconductor device. Through this, the embodiment can improve the circuit integration. Furthermore, the embodiment can minimize a transmission distance of a signal transmitted through the semiconductor device, thereby minimizing signal transmission loss.

The circuit board 100 described above may generate gas during the process, which may reduce the adhesion between the first to fourth insulating layers 112, 113, 114, and 115 and the first to sixth circuit layers 121, 122, 123, 124, 125, and 126. In addition, when the adhesion is reduced, an interface between the first to fourth insulating layers 112, 113, 114, and 115 and the first to sixth circuit layers 121, 122, 123, 124, 125, and 126 may peel off, which may cause mechanical reliability and/or electrical reliability problems. Accordingly, at least one of the first to sixth circuit layers 121, 122, 123, 124, 125, and 126 may be provided with a through hole 120a. At this time, the through hole 120a may be provided in each of the first to sixth circuit layers 121, 122, 123, 124, 125, and 126, and accordingly, the gas generated during the curing of the first to fourth insulating layers 112, 113, 114, and 115 may be easily exhausted.

Referring to FIG. 2, the circuit board may include an insulating layer 210 and a circuit layer 220 disposed on the insulating layer 210. At this time, the insulating layer 210 may refer to any one of the first to fourth insulating layers 112, 113, 114, and 115 described in FIG. 1, and the circuit layer 220 may refer to any one of the first to sixth circuit layers 121, 122, 123, 124, 125, and 126.

The circuit layer 220 may include a plurality of circuit patterns spaced apart from each other in the horizontal direction. In this case, the through hole 220a may have a different meaning from a separation region between the plurality of circuit patterns. The circuit layer 220 may include a plurality of circuit patterns disposed on a same plane of the insulating layer 210 and spaced apart from each other in the horizontal direction. In addition, the separation region between the plurality of circuit patterns may have a different meaning from the through hole 220a. The separation region may mean a hole provided between the plurality of circuit patterns that must be electrically separated from each other. In addition, the through hole 220a may mean a hole passing through upper and lower surfaces of one circuit pattern. In addition, the separation region may also be expressed as a spacing between multiple circuit patterns. The spacing may have a range of 20 μm or less, 18 μm or less, 15 μm or less, or 12 μm or less for miniaturization of the circuit layer 220.

The through hole 220a is provided in the circuit layer 220 and may function as a gas exhaust hole for exhausting gas generated in the insulating layer 210. Therefore, the through hole 220a may also be functionally called a degassing hole.

In one embodiment, a planar shape of the through hole 220a may be a circular shape. However, the embodiment is not limited thereto. In another embodiment, a planar shape of the through hole 220a may have a triangular, square, oval, rhombus, or polygonal shape. In addition, at least one of the plurality of through holes 220a provided in the circuit layer 220 may have a first planar shape, and at least one other through hole 220a may have a second planar shape different from the first planar shape.

The through hole 220a of the circuit layer 220 may function as a gas exhaust hole for exhausting gas generated in the insulating layer 210.

For example, to briefly explain the manufacturing process of a circuit board 100, the insulating layer 210 may be provided in a semi-cured state. Then, the circuit layer 220 may be disposed on the insulating layer 210 in a semi-cured state. In this case, a process of completely curing the insulating layer 210 may be performed after the circuit layer 220 is disposed.

At this time, when a process of completely curing the insulating layer 210 is performed, gas may be generated in the insulating layer 210. At this time, the generated gas must be exhausted from the insulating layer 210 to the outside of the circuit board 100. At this time, the circuit layer 220 is disposed on the insulating layer 210. Accordingly, a problem may occur in which the gas generated from the insulating layer 210 is not exhausted to the outside of the circuit board 100 by the circuit layer 220.

Therefore, the circuit layer 220 of the embodiment may have a through hole 220a passing through the upper and lower surfaces. The through hole 220a of the circuit layer 220 may function as a gas exhaust hole that exhausts the gas generated from the insulating layer 210 to the outside of the circuit board 100 (for example, in an upper direction of the circuit layer away from the insulating layer 210). The embodiment is provided with a through hole 220a in the circuit layer 220, so that gas generated in the insulating layer 210 can be easily exhausted to the outside of the circuit board 100. Through this, the embodiment can solve a physical reliability problem that occurs due to gas remaining in the insulating layer 210. For example, if gas generated in the insulating layer 210 is not exhausted, a problem may occur in which at least one of the insulating layer 210 and the circuit layer 220 swells due to the gas.

For example, referring to FIG. 5(a), the circuit layer of the circuit board of a comparative example is not provided with a through hole. As a result, the circuit board of the comparative example may have a problem in which gas generated in the insulating layer 10 is not exhausted to an upper side of the circuit layer 20. Accordingly, the circuit board of the comparative example may include a portion in which the insulating layer 10 and the circuit layer 20 swell due to the gas. For example, the insulating layer 10 of the circuit board of the comparative example may include a convex region 10P in which one region bulges upward and/or a concave region (A) that is concavely sunken to correspond to the convex region 10P. In addition, the circuit layer 20 of the circuit board of the comparative example may include a convex region 20P in which one region bulges upward to correspond to the convex region 10P. In the convex region 10P and 20P, the adhesion between the insulating layer 10 and the circuit layer 20 is reduced, and thus, a physical reliability problem such as peeling between the circuit layer 20 and the insulating layer 10 may occur. In addition, the adhesion between the plurality of insulating layers is reduced by the concave region (A), and thus, an adhesion problem in which the plurality of insulating layers are physically separated from each other may occur.

In addition, referring to (b) of FIG. 5, the circuit board of the comparative example includes a portion where the insulating layer 10 and/or the circuit layer 20 swells due to gas. For example, the circuit layer 20 of the circuit board of the comparative example may include a convex region 20P in which one region swells upward from the insulating layer 10. In addition, a surface (B) corresponding to the convex region 20P of the circuit layer 20 may not contact the insulating layer 10. As a result, the adhesion between the circuit layer 20 and the insulating layer 10 may be reduced due to the convex region 20P, and thus, a physical reliability problem may occur in which the circuit layer 20 is separated from the insulating layer 10.

In contrast, referring to FIG. 6, the circuit layer 220 of the embodiment is provided with a through hole 220a, and gas generated in the insulating layer 210 can be smoothly exhausted to the outside of the circuit board 100 through the through hole 220a. Through this, the embodiment can prevent the insulating layer 210 and/or the circuit layer 220 from including a region that swells due to gas. Accordingly, the embodiment can improve the adhesion between a plurality of insulating layers, and the adhesion between the insulating layer and the circuit layer. Through this, the embodiment can improve the physical reliability of the circuit board.

At this time, the through hole 220a of the circuit layer 220 can be filled with an insulating material. That is, the through hole 220a of the circuit layer 220 can be filled with another insulating layer and/or a protective layer that are laminated on the circuit layer 220 in the lamination process of the circuit board 110.

It may be difficult to improve the gas exhaust characteristics simply by providing a through hole 220a in the circuit layer 220 without any conditions. Furthermore, if a through hole 220a is provided in the circuit layer 220, a wiring density of the circuit layer 220 may decrease, which may cause a problem in which the circuit board 100 is significantly warped in a specific direction. For example, the gas exhaust characteristics and/or the warpage characteristics of the circuit board 100 may be determined according to a diameter W3 of the through hole 220a provided in the circuit layer 220.

For example, if the diameter W3 of the through hole 220a is too small, the gas generated in the insulating layer 210 may not be properly exhausted to the outside of the circuit board 200, and thus an effect of improving the adhesion between the insulating layer 210 and the circuit layer 220 may be insufficient.

For example, if the diameter W3 of the through hole 220a is too large, an area or wiring density of the circuit layer 220 on a single layer of the insulating layer 210 may decrease. In addition, if the area or density of the circuit layer 220 decreases, the warpage characteristic of the circuit board 100 may deteriorate, and as a result, the circuit board 100 may be greatly warped in a specific direction. If the circuit board 100 is greatly warped in a specific direction, it may be difficult to secure a uniform contact surface when the semiconductor package is mounted on the main board. Alternatively, when the circuit board 100 is bent due to heat generated during the operation of the semiconductor device, it may be difficult to operate the semiconductor device smoothly, and it may be difficult to operate the server or the electronic product smoothly. Therefore, the diameter W3 of the through hole 220a relative to a planar area of the circuit board 100 can be directly related to the reliability of electronic products such as servers to which the semiconductor package is applied, and thus can have technical interoperability or functional integrity. In addition, if the circuit board 100 is significantly bent in a specific direction, a process error may occur during the manufacturing process of the circuit board 100, which may result in a problem of reduced yield.

Therefore, the embodiment determines the diameter W3 of the through hole 220a based on the planar area of the circuit board 100. Accordingly, the embodiment solves the problem of bending the circuit board 100, and allows the gas generated from the insulating layer 210 to be well exhausted to the outside of the circuit board 100.

The planar area of the circuit board 100 may mean a planar area of the insulating layer 210. The insulating layer 210 may have a first width W1 in a first horizontal direction (e.g., x-axis direction, or horizontal direction). In addition, the insulating layer 210 may have a second width W2 in a second horizontal direction (e.g., y-axis direction, or vertical direction) perpendicular to the first horizontal direction.

In addition, the planar area of the circuit board 100 having the first width W1 and the second width W2 may be 1500 mm² to 2000 mm² . Preferably, the planar area of the circuit board 100 having the first width W1 and the second width W2 may be 1550 mm² to 1950 mm² . More preferably, the planar area of the circuit board 100 having the first width W1 and the second width W2 may be 1580 mm² to 1900 mm².

In addition, when the circuit board 100 has the planar area as described above, a minimum value of a diameter W3 of the through hole 220a provided in the circuit layer 220 must have a certain level so that the gas generated in the insulating layer 210 can be smoothly exhausted to the outside of the circuit board 100.

For example, there may be a plurality of through holes 220a provided in the circuit layer 220. In addition, at least one of a plurality of through holes 220a must have a diameter W3 of a predetermined level or higher, and as the at least one through hole 220a has a diameter W3, the gas generated in the insulating layer 210 may be easily exhausted to the outside.

The diameter W3 of the through hole 220a may be at least 165 μm or greater. If the diameter W3 of the through hole 220 a is smaller than 165 μm, the gas generated from the insulating layer 210 having the planar area may not be properly exhausted to the upper side of the circuit layer 220. In addition, if the gas is not exhausted, the circuit layer 220 and/or the insulating layer 210 may swell. As a result, the adhesion between the circuit layer 220 and the insulating layer 210 may be reduced.

Meanwhile, the larger the diameter W3 of the through hole 220a, the better the gas generated from the insulating layer 210 can be exhausted to the outside. However, if the diameter of the through hole 220a is too large, the wiring density or area of the circuit layer 220 on the insulating layer 210 may decrease. In addition, when the wiring density or area of the circuit layer 220 decreases, the characteristics of the circuit layer 220 may change or the warpage characteristics of the circuit board 100 may deteriorate. Here, the characteristics of the circuit layer 220 may mean impedance characteristics, but are not limited thereto. In addition, the circuit layer 220 may perform a wiring function while also preventing the circuit board 100 from bending. In addition, when the diameter W3 of the through hole 220a provided in the circuit layer 220 is too large, the circuit board 100 cannot be prevented from bending, and thus, a problem may occur in which the circuit board 100 bends significantly in a specific direction.

The diameter W3 of the through hole 220 a may satisfy a range of 165 μm to 220 μm. Preferably, the diameter W3 of the through hole 220 a can satisfy a range of 165 μm to 210 μm. More preferably, the diameter W3 of the through hole 220 a can satisfy a range of 165 μm to 205 μm. If the diameter W3 of the through hole 220 a is less than 165 μm, as described above, the gas generated in the insulating layer 210 is not properly discharged to the outside of the circuit board 100, and thus, a problem may occur in which the gas remains in the insulating layer 210. In addition, if the gas remains, the insulating layer 210 and/or the circuit layer 220 may swell, resulting in a physical reliability problem. In addition, if the diameter W3 of the through hole 220 a exceeds 220 μm, the area or density of the circuit layer 220 decreases, and accordingly, the impedance characteristics between the multiple circuit layers may change, or the rigidity of the circuit board 100 may decrease.

In addition, a ratio of the diameter of the through hole 220a to the planar area of the insulating layer 210 may satisfy a range of 0.0000825 to 0.000147. In addition, a ratio of the planar area of the through hole 200a to the planar area of the insulating layer 210 may satisfy a range of 0.00025905 to 0.0004605. That is, the planar area of the insulating layer 210 can be 1500 mm² to 2000 mm² , at least one of the plurality of through holes 220 a can have a diameter of 165 μm to 220 μm, and the planar area of at least one of the plurality of through holes 220a can satisfy a range of 518.1 μm² to 690.8 μm².

Through this, the embodiment can solve the problem that the gas generated by the insulating layer 210 is well exhausted to the outside of the circuit board 100, and furthermore, the embodiment can solve the problem of decreasing the area or wiring density of the circuit layer, the change in impedance characteristics between multiple circuit layers, and the problem of lowering the rigidity of the circuit board 100.

Referring to FIG. 4, the through electrode 230 can be provided while passing through the insulating layer 210. At this time, the circuit layer 220 having the through hole 220a may overlap with the through electrode 230 in the vertical direction. At this time, the through hole 220a provided in the circuit layer 220 may not overlap with the through electrode 230 in the vertical direction. At this time, if the through hole 220a of the circuit layer 220 overlaps with the through electrode 230 in the vertical direction, the electrical connection characteristics between the plurality of circuit layers by the through electrode 230 may be deteriorated. That is, the through electrode 230 may connect between the circuit layers disposed in different insulating layers. In addition, if the through hole 220a of the circuit layer 220 overlaps with the through electrode 230 in the vertical direction, the transmission loss of the signal transmitted through the through electrode 230 may increase, and thus the signal transmission reliability may be deteriorated. Accordingly, the through hole 220a provided in the circuit layer 220 of the embodiment can be made not to overlap vertically with the through electrode 230 passing through the insulating layer 210.

In addition, the diameter W3 of the through hole 220a provided in the circuit layer 220 may be larger than the diameter of the through electrode 230. At this time, the through electrode 230 may have a slope whose width gradually changes from the upper surface to the lower surface of the insulating layer 210 as illustrated in FIG. 2. In addition, the diameter W3 of the through hole 220a may be larger than a width W4 of a region having a largest width in an entire region in the vertical direction of the through electrode 230.

For example, the width W4 of the through electrode 230 may satisfy a range of 60 μm to 90 μm. For example, the width W4 of the through electrode 230 may satisfy a range of 60 μm to 85 μm. For example, the width W4 of the through electrode 230 may satisfy a range of 60 μm to 80 μm. If the width W4 of the through electrode 230 is less than 60 μm, an allowable current of the signal that can be transmitted through the through electrode 230 decreases, and thus the electrical characteristics of the circuit board and the semiconductor package may deteriorate. If the width W4 of the through electrode 230 exceeds 90 μm, a process time for filling the through electrode 230 with a conductive material increases, and thus the product production yield may decrease. In addition, if the width W4 of the through electrode 230 exceeds 90 μm, a pitch between the plurality of through electrodes spaced apart in the horizontal direction increases, and thus the circuit integration may decrease.

In summary, the diameter W3 of the through hole 220a provided in the circuit layer 220 may be 2.5 times or more the width W4 of the through electrode 230. In addition, if the diameter W3 of the through hole 220a provided in the circuit layer 220 is less than 2.5 times the width W4 of the through electrode 230, the gas generated in the insulating layer 210 may not be easily exhausted to the outside of the circuit board 100.

In addition, according to the embodiment of FIG. 7, the circuit layer 220 may be provided with a through hole 220a having a rhombus shape instead of a circular shape. In addition, when the through hole 220a provided in the circuit layer 220 has a rhombus shape, the diameter W3 of the through hole 220a may mean a distance between vertices facing each other on a plane of the through hole 220a.

In addition, according to the embodiment of FIG. 8, the diameter W3 of each of the plurality of through holes 320a provided in the circuit layer 320 may be equal to or greater than a separation distance W4 between two mutually adjacent through holes among the plurality of through holes 320a. That is, the diameter W3 of each of the plurality of through holes 320a provided in the circuit layer 320 may be equal to or greater than the separation distance W4 between two mutually adjacent through holes among the plurality of through holes 320a. At this time, if the diameter W3 of each of the plurality of through holes 320a is smaller than the separation distance W4 between two mutually adjacent through holes among the plurality of through holes 320a, the gas generated in the insulating layer 310 may not be easily exhausted to the outside of the circuit board 100. The fact that the diameter W3 of the through hole 320a is smaller than the separation distance W4 may mean that, based on the region where the through hole 320a is disposed in the circuit layer 320, the region where the gas cannot be exhausted through the through hole 320a is larger than the region where the gas can be exhausted through the through hole 320a. In addition, when the diameter W3 of the through hole 320a is larger than the separation distance W4 between the plurality of through holes 320a, the gas may not be properly exhausted and may remain in the insulating layer 310, and thus the physical characteristics may deteriorate.

At this time, the separation distance W4 may vary depending on an arrangement direction and/or arrangement form of the plurality of through holes 320a. For example, in the case where a plurality of through holes 320a are provided in a zigzag shape in a diagonal direction as in FIG. 8, the separation distance W4 may mean a separation distance between two through holes located diagonally from each other among the plurality of through holes.

For example, in the case where the plurality of through holes 320a are provided at a certain spacing in a first horizontal direction parallel to a first side surface of the circuit board or in a second horizontal direction perpendicular to the first surface as in the embodiment of FIG. 9, the separation distance W4 may mean a separation distance between two through holes located in the first horizontal direction or the second horizontal direction among the plurality of through holes.

At this time, the diameter of at least one of the plurality of through holes 320a may be different from the diameter of at least one other. Separation distances between a plurality of through holes adjacent to each other among a plurality of through holes may be different from each other. In this case, the diameter W3 may mean a diameter of the through hole having a smallest diameter among the multiple through holes 320a. In addition, the separation distance may mean a largest separation distance among the separation distances between the plurality of through holes adjacent to each other.

In other words, the smallest diameter among the diameters of each of the plurality of through holes 320a of the embodiment may be equal to or greater than the largest separation distance among the separation distances between the plurality of through holes adjacent to each other. Through this, the embodiment may enable the gas generated in the insulating layer 310 to be discharged better, and thus further improve the physical reliability of the circuit board and semiconductor package.

At this time, since the diameter W3 of the through hole 320a has been described with reference to FIG. 3, a detailed description thereof will be omitted.

The separation distance W4 may be determined based on the diameter W3 of the through hole 320a and the width W5 of the through electrode 330. The separation distance W4 may be less than or equal to the diameter W3 of the through hole 320a and greater than or equal to the width W5 of the through electrode 330. If the separation distance W4 is less than the width W5 of the through electrode 330, the through hole 320a and the through electrode 330 may overlap in the vertical direction, or an area of a region overlapping in the vertical direction may increase. In addition, when an area of the region overlapping in the vertical direction increases, the signal transmission characteristics of the through electrode 330 may deteriorate. Furthermore, as described above, the separation distance W4 may mean a separation distance between two through holes that are disposed adjacent to each other among the plurality of through holes 320a. For example, based on one first through hole, the second through hole that is disposed most adjacent to the first through hole may be located in a diagonal horizontal direction of the first through hole. Therefore, the separation distance W4 may mean a separation distance between two through holes that are spaced apart from each other in the diagonal horizontal direction. However, the embodiment is not limited thereto. For example, if the second through hole that is closest to the first through hole is located in the horizontal direction (e.g., x-axis direction) or the vertical direction (e.g., y-axis direction), the separation distance may mean a separation distance between the first and second through holes located in the horizontal direction or the vertical direction.

In addition, according to the embodiment of FIG. 10, the through electrode 330 may be provided so as to pass through the insulating layer 310, and the circuit layer 320 provided with the through hole 320a may overlap with the through electrode 330 in the vertical direction. At this time, the through hole 320a provided in the circuit layer 320 may not overlap with the through electrode 330 in the vertical direction. At this time, when the through hole 320a of the circuit layer 320 overlaps with the through electrode 330 in the vertical direction, the electrical connection characteristics between the plurality of circuit layers by the through electrode 330 may be deteriorated. That is, the through electrode 330 may connect between the circuit layers disposed in different insulating layers. In addition, when the through hole 320a of the circuit layer 320 overlaps with the through electrode 330 in the vertical direction, the transmission loss of the signal transmitted through the through electrode 330 may increase, and the signal transmission reliability may deteriorate accordingly. Therefore, the through hole 320a provided in the circuit layer 320 of the embodiment is designed so as not to overlap with the through electrode 330 passing through the insulating layer 310 in the vertical direction, or even if the through hole 320a and the through electrode 330 overlap in the vertical direction, an area of an overlapping region can be minimized.

In addition, according to the embodiment of FIGS. 11 and 12, the circuit board may include a first circuit layer 421 disposed on the insulating layer 411. The first circuit layer 421 may be divided into a plurality of regions. For example, the first circuit layer 421 may be divided into a plurality of regions based on a plurality of circuit patterns provided in the second circuit layer 422. For example, the first circuit layer 421 may include first to third regions R1, R2, and R3. The first region R1 of the first circuit layer 421 may include a plurality of first through holes 421-1 passing through upper and lower surfaces of the first region R1. The plurality of first through holes 421-1 may have a first diameter W3. The first diameter W3 of the first through holes 421-1 provided in the first region R1 may be determined based on the planar area of the circuit board 100. In this case, the first diameter W3 of the first through hole 421-1 may correspond to the diameter of the through hole 220a and 320a described in at least one of the embodiments of FIG. 3, FIG. 4, FIG. 6, FIG. 7, FIG. 8, FIG. 9, and FIG. 10.

The first circuit layer 421 may include a second region R2 distinguished from the first region R1 on the insulating layer 411. In one embodiment, the first region R1 and the second region R2 may be distinguished by regions from a single circuit pattern that is connected to each other in the first circuit layer 421. In another embodiment, the first region R1 and the second region R2 may be distinguished by a plurality of circuit patterns that are spaced apart from each other in the first circuit layer 421. The second region R2 may include a plurality of second through holes 421-2 that pass through upper and lower surfaces of the second region R2 of the first circuit layer 421. At this time, the plurality of second through holes 421-2 provided in the second region R2 may have a second diameter W4. At this time, each second diameter W4 of the plurality of second through holes 421-2 provided in the second region R2 may be different from the first diameter W3 of each of the plurality of first through holes 421-1 provided in the first region R1. Preferably, each second diameter W4 of the plurality of second through holes 421-2 provided in the second region R2 may be larger than the first diameter W3 of each of the plurality of first through holes 421-1 provided in the first region R1. This may be due to the characteristics of the circuit patterns of the second circuit layer 422 which vertically overlap with the first region R1 and the second region R2 of the first circuit layer 421. The characteristics of the circuit patterns of the second circuit layer 422 may mean any one of the wiring density of the circuit patterns, the width/spacing of the circuit patterns, and the function of the circuit patterns. In addition, the first circuit layer 421 may include a third region R3 that is distinct from the first region R1 and the second region R2. The third region R3 of the first circuit layer 421 may be distinct from the first region R1 and the second region R2 depending on the arrangement position on the insulating layer 411. The third region R3 may be connected to the first region R1 and the second region R2, but is not limited thereto. The third region R3 may be physically and/or electrically separated from the first region R1 and the second region R2. The third region R3 may be disposed closer to a periphery of the circuit board 100 than the first region R1 and the second region R2. The third region R3 may be provided along an edge and/or a circumferential direction of the upper surface of the first circuit layer 421. For example, the third region R3 may mean an edge region of the upper surface of the first circuit layer 421. In other words, an upper surface of the insulating layer 411 may include an edge region adjacent to an edge. In addition, the third region R3 may mean a region that overlaps the edge region of the insulating layer 411 in the vertical direction among the first circuit layer 421.

The first region R1 and the second region R2 may mean an inner region of the edge region corresponding to the third region R3. The third region R3 of the first circuit layer 421 may include a plurality of third through holes 421-3 passing through upper surface and the lower surface of the third region R3. Each of the plurality of third through holes 421-3 provided in the third region R3 may have a third diameter W5. At this time, the third diameter W5 of each of the plurality of third through holes 421-3 provided in the third region R3 may be different from the first diameter W3 of each of the plurality of first through holes 421-1 provided in the first region R1 and the second diameter W4 of each of the plurality of second through holes 421-2 provided in the second region R2. Preferably, the third diameter W5 of each of the plurality of third through holes 421-3 provided in the third region R3 may be smaller than the first diameter W3 of each of the plurality of first through holes 421-1 provided in the first region R1 and the second diameter W4 of each of the plurality of second through holes 421-2 provided in the second region R2.

To summarize, the first circuit layer 421 is disposed on the insulating layer 411 and can be divided into a first region R1, a second region R2, and a third region R3 along a horizontal direction. In addition, the first region R1 of the first circuit layer 421 can have a plurality of first through holes 421-1. In addition, the second region R2 of the first circuit layer 421 can have a plurality of second through holes 421-2. In addition, the third region R3 of the first circuit layer 421 can have a plurality of third through holes 421-3. At this time, among the first through hole 421-1, the second through hole 421-2, and the third through hole 421-3, the second through hole 421-2 can have a largest diameter, and the third through hole 421-3 can have a smallest diameter. This may be due to the positions of the first region R1, the second region R2, and the third region R3 of the first circuit layer 421, and/or the characteristics of the circuit pattern of the second circuit layer 422 overlapping the regions in a vertical direction.

The second circuit layer 422 may be disposed on the lower surface of the insulating layer 411. The second circuit layer 422 may include a plurality of circuit patterns. The circuit patterns of the second circuit layer 422 may have different wiring densities. The wiring density may mean an area occupied by the second circuit layer 422 within a specific unit area of the insulating layer 411. The second circuit layer 422 may include a first circuit pattern 422-1 overlapping the first region R1 of the first circuit layer 421 in the vertical direction. In addition, the second circuit layer 422 may include a second circuit pattern 422-2 overlapping the second region R2 of the first circuit layer 421 in the vertical direction and spaced from the first circuit pattern 422-1 in the horizontal direction. In addition, the second circuit layer 422 may include a third circuit pattern 422-3 overlapping the third region R3 of the first circuit layer 421 in the vertical direction. The third circuit pattern 422-3 may refer to a circuit pattern disposed in an edge region of the lower surface of the insulating layer 411 corresponding to the third region R3 of the first circuit layer 421. In addition, the first circuit pattern 422-1 and the second circuit pattern 422-2 of the second circuit layer 422 may refer to circuit patterns that are disposed inside the edge region of the lower surface of the insulating layer 411 among the second circuit layers 422.

At this time, the first circuit pattern 422-1 and the second circuit pattern 422-2 of the second circuit layer 422 may have different wiring densities. Specifically, the second circuit pattern 422-2 of the second circuit layer 422 may have a greater density than the first circuit pattern 422-1. The width and spacing of the circuit pattern 422-2 in the second region may be smaller than the width and spacing of the circuit pattern 422-1 in the first region. In addition, if a through hole with a relatively small diameter is provided in the second region R2 of the first circuit layer 421 overlapping the second circuit pattern 422-2 in the vertical direction, the characteristics of the second circuit patterns 422-2 having a relatively high wiring density may change. For example, the second circuit pattern 422-2 may be a circuit pattern for impedance matching. At this time, if a through hole with a relatively small diameter is provided in the second region R2 of the first circuit layer 421 overlapping the second circuit pattern 422-2 in the vertical direction, the impedance characteristic of the second circuit pattern 422-2 of the second circuit layer 422 may change. In addition, if a through hole with a relatively small diameter is provided in the second region R2 of the first circuit layer 421 overlapping the second circuit pattern 422-2 in the vertical direction, the second circuit pattern 422-2 may be damaged. In addition, if a through hole with a relatively small diameter is provided in the second region R2 of the first circuit layer 421 overlapping the second circuit pattern 422-2 in the vertical direction, the gas in the insulating layer 411 corresponding to the third region R3 may not be easily exhausted to the outside, and thus the physical characteristics and/or electrical characteristics of the circuit board and the semiconductor package may be deteriorated.

Accordingly, in the embodiment, the second diameter W4 of each of the plurality of second through holes 421-2 provided in the second region R2 of the first circuit layer 421 is larger than the first diameter W3 of each of the plurality of first through holes 421-1 provided in the first region R1 of the first circuit layer 421. Accordingly, the embodiment enables the gas generated in the insulating layer 411 to be exhausted to the upper side of the first circuit layer 421 without affecting the impedance characteristic of the second circuit pattern 422-2.

However, the embodiment differs in the gas exhaust amount for each region in the first circuit layer 421, so that the gas generated in the insulating layer 411 can be completely removed without changing the characteristics of the second circuit layer 422 disposed under the first circuit layer 421.

Specifically, the gas generated in the insulating layer 411 of the embodiment can be concentratedly exhausted through the plurality of second through holes 421-2 provided in the second region R2 of the first circuit layer 421 having a relatively large diameter. That is, when the adhesion between the second region R2 and the insulating layer 411 is reduced, the electrical characteristics of the second circuit pattern 422-2 may be reduced. Therefore, the embodiment allows the diameters of the plurality of second through holes 421-2 provided in the second region R2 to be larger than the diameters of the through holes provided in other regions. However, when the gas generated in the insulating layer 411 is exhausted only through the second through holes 421-2 of the second region R2, the gas inside the insulating layer 411 may not be completely exhausted. Therefore, the embodiment can allow a portion of the gas of the insulating layer 411 to be exhausted even through the first through hole 421-1 of the first region R1 of the first circuit layer 421 having a relatively small diameter. Through this, the embodiment can completely exhaust the gas generated in the insulating layer 411 to the outside of the circuit board 100. Therefore, the embodiment can further improve the physical characteristics and/or electrical characteristics of the circuit board and the semiconductor package.

Furthermore, the third region R3 of the first circuit layer 421 can be a portion disposed in the edge region of a surface of the insulating layer 411. At this time, the circuit pattern disposed in the edge region of the insulating layer 411 can affect the rigidity of the circuit board and the semiconductor package. That is, if the diameter of the third through hole 421-3 provided in the third region R3 of the first circuit layer 421 is large, an area of the third region R3 in the edge region of the insulating layer 411 may also decrease. In addition, if the area of the third region R3 in the edge region decreases, the rigidity of the circuit board and the semiconductor package may decrease. For example, if the area of the third region R3 in the edge region decreases, a problem may occur in which the circuit board and the semiconductor package are greatly bent in a specific direction. Therefore, the embodiment allows the diameter of the third through hole 421-3 provided in the third region R3 to be smaller than each of the diameters of the first through hole 421-1 and the second through hole 421-2. Therefore, the embodiment prevents the circuit board and the semiconductor package from being bent in a specific direction, while allowing gas generated in the insulating layer 411 to be completely exhausted to the outside of the circuit board 100. Through this, the embodiment can further improve the physical characteristics and/or electrical characteristics of the circuit board and the semiconductor package.

At this time, although the third region R3 is described as a circuit pattern disposed in the edge region of the insulating layer 411, but the embodiment is not limited thereto. For example, unlike the first region R1 and the second region R2, the third region R3 may mean a circuit pattern disposed in the edge region of the insulating layer.

In addition, among the plurality of first through holes 421-1 provided in the first region R1, two adjacent first through holes may be spaced apart from each other with a first separation distance. In addition, among the plurality of second through holes 421-2 provided in the second region R2, two adjacent second through holes may be spaced apart from each other with a second separation distance. In addition, among the plurality of third through holes 421-3 provided in the third region R3, two adjacent third through holes may be spaced apart from each other by a third separation distance. At this time, the first separation distance, the second separation distance, and the third separation distance may be different from each other. Preferably, the second separation distance may be the smallest among the first separation distance, the second separation distance, and the third separation distance. In addition, the third separation distance may be the largest among the first separation distance, the second separation distance, and the third separation distance. That is, the embodiment allows the separation distance between the plurality of second through holes 421-2 to be the smallest. Accordingly, the embodiment allows a second through hole 421-2 having a larger area to be provided in the second region R2. Accordingly, the embodiment enables the gas generated in the insulating layer 411 to be completely exhausted, while improving the electrical characteristics of the second circuit pattern 422-2. In addition, the embodiment can make the first separation distance of the first through hole 421-1 larger than the second separation distance, so that the gas generated in the insulating layer 411 by the first through hole 421-1 can be completely exhausted. In addition, the embodiment can make the third separation distance of the third through hole 421-3 larger than each of the first separation distance and the second separation distance, so that the gas generated in the insulating layer 411 can be completely exhausted without affecting the rigidity of the circuit board and the semiconductor package.

At this time, the diameter W3 of the plurality of first through holes 421-1 provided in the first region R1 and a first separation distance between the plurality of first through holes will be described. In addition, a diameter W4 and a separation distance of the plurality of second through holes 421-2 provided in the second region R2, and a diameter W5 and a separation distance of the plurality of third through holes 421-3 provided in the third region R3 can have a range satisfying conditions based on the description below.

The diameter W3 of each of the plurality of first through holes 421-1 provided in the first region R1 of the first circuit layer 421 may be equal to or greater than a separation distance between two adjacent first through holes among the plurality of first through holes 421-1. That is, the diameter W3 of each of the plurality of first through holes 421-1 provided in the first region R1 may be equal to or greater than the separation distance between two adjacent first through holes among the plurality of first through holes 421-1. At this time, if the diameter W3 of each of the plurality of first through holes 421-1 is smaller than the separation distance between two adjacent through holes among the plurality of first through holes 421-1, the gas generated in the insulating layer 411 may not be easily exhausted to the outside of the circuit board 100. That is, the fact that the diameter W3 of the first through hole 421-1 is smaller than the separation distance between the plurality of first through holes may mean that, with respect to the region in which the first through hole 421-1 is disposed in the first region R1, the region where the gas cannot be exhausted is larger than the region where the gas can be exhausted through the first through hole 421-1. In addition, if the separation distance between the plurality of first through holes 421-1 is larger than the diameter W3 of the first through hole 421-1, the gas may not be exhausted well and may remain in the insulating layer 411, and thus the physical characteristics may deteriorate. At this time, the separation distance may vary depending on an arrangement direction of the plurality of first through holes 421-1. For example, if a plurality of first through holes 421-1 are disposed in a zigzag shape in a diagonal direction in the first region R1, the separation distance may mean a separation distance between two first through holes that are located diagonally from each other among the plurality of first through holes. In addition, if a plurality of first through holes 421-1 are provided with a predetermined spacing in a first horizontal direction parallel to a first side surface of the circuit board or a second horizontal direction perpendicular to the first side surface, the separation distance may mean a separation distance between two first through holes that are located adjacently in the first horizontal direction or the second horizontal direction among the plurality of first through holes.

In addition, the embodiment allows the diameter W3 of at least one first through hole 421-1 among the plurality of first through holes 421-1 to be equal to or greater than a certain level while ensuring that the diameter W3 of the first through hole 421-1 is equal to or greater than the separation distance between the through holes. The diameter W3 of the first through hole 421-1 may be determined based on the planar area of the circuit board 100. That is, if the diameter W3 of the first through hole 421-1 is too small compared to the planar area of the circuit board 100, the gas generated from the insulating layer 411 may not be properly exhausted to the outside of the circuit board 100, and thus the effect of improving the adhesion between the insulating layer 411 and the circuit layers may be insufficient.

In addition, as described above based on the previous embodiment, the diameter W3 of the first through hole 421-1 may be at least 165 μm or more. Furthermore, as described above, the diameter W3 of the first through hole 421-1 may satisfy a range of 165 μm to 220 μm. Preferably, the diameter W3 of the first through hole 421-1 can satisfy a range of 165 μm to 210 μm. More preferably, the diameter W3 of the first through hole 421-1 can satisfy a range of 165 μm to 205 μm. In addition, as described above, a ratio of the diameter of the first through hole 421-1 to the area of the insulating layer 411 can satisfy a range of 0.0000825 to 0.000147. In addition, as described above, a ratio of the planar area of the first through hole 421-1 to the planar area of the insulating layer 411 can satisfy a range of 0.00025905 to 0.0004605. That is, the planar area of the insulating layer 411 may be 1500 mm² to 2000 mm² , at least one of the plurality of first through holes 421-1 may have a diameter of 165 μm to 220 μm, and the planar area of at least one of the plurality of first through holes 421-1 may satisfy a range of 518.1 μm² to 690.8 μm² . In addition, the separation distance between the plurality of first through holes 421-1 may be less than or equal to the diameter W3 of the first through hole 421-1 and greater than or equal to the width of the through electrode 430. If the separation distance is less than the width of the through electrode 430, the first through hole 421-1 and the through electrode 430 may overlap in the vertical direction, or an area of a region overlapping in the vertical direction may increase. In addition, if the area of the region overlapping in the vertical direction increases, the signal transmission characteristics of the through electrode 430 may deteriorate.

For example, referring to the embodiment of FIG. 14, the through electrode 430 may be provided to pass through the insulating layer 411. At this time, the first through hole 421-1, the second through hole 421-2, and the third through hole 421-3 provided in the first circuit layer 421 may not vertically overlap with the through electrode 430 disposed in a first layer of the insulating layer. Through this, the embodiment minimizes the transmission loss of the signal transmitted through the through electrode 430. In addition, the diameter of the through hole provided in each of the circuit patterns described above may be larger than the diameter of the through electrode 430.

That is, the diameter W3 of the first through hole 421-1 provided in the first region R1, the diameter W4 of the second through hole 421-2 provided in the second region R2, and the diameter W5 of the third through hole 421-3 provided in the third region R3 may each be larger than the diameter of the through electrode 430.

At this time, the through electrode 430 may have a slope whose width gradually changes from the upper surface to the lower surface of the insulating layer 411. In addition, the diameter W3 of the first through hole 421-1 provided in the first region R1, the diameter W4 of the second through hole 421-2 provided in the second region R2, and the diameter W5 of the third through hole 421-3 provided in the third region R3 may each be larger than a width of a region having a largest width in the through electrode 430.

Furthermore, the first circuit layer 421 may include a pad 421-5 overlapping the through electrode 430 in a vertical direction. The pad 421-5 may be a circuit pattern connected to the through electrode 430. In addition, the first circuit layer 421 may include a fourth through hole 121-4 provided corresponding to the region where the pad 421-5 is disposed. At this time, the fourth through hole 421-4 may have a different function from the first to third through holes 421-1, 421-2, and 421-3.

That is, the first to third through holes 421-1, 421-2, and 421-3 can function as gas exhaust holes, and accordingly, other circuit patterns of the first circuit layer 421 may not be disposed in inner regions of the first to third through holes 421-1, 421-2, and 421-3. That is, the inner regions of the first to third through holes 421-1, 421-2, and 421-3 may be filled with other insulating layers disposed thereon.

Alternatively, the fourth through hole 421-4 may be a separation region for separating the pad 421-5 from another circuit pattern. Accordingly, other circuit patterns of the first circuit layer 421 may be disposed in the inner region of the fourth through hole 421-4. For example, a pad 421-5 of the first circuit layer 421 may be disposed in the inner region of the fourth through hole 421-4. In addition, the diameter of the fourth through hole 421-4 may be smaller than the diameters of the first to third through holes 421-1, 421-2, and 421-3.

To summarize, the diameter W3 of the first through hole 421-1 provided in the first region R1, the diameter W4 of the second through hole 421-2 provided in the second region R2, and the diameter W5 of the third through hole 421-3 provided in the third region R3 may each be larger than the width of the through electrode 430. In addition, the diameter W4 of the second through hole 421-2 provided in the second region R2 may be larger than the diameter W3 of the first through hole 421-1 provided in the first region R1 and the diameter W5 of the third through hole 421-3 provided in the third region R3. In addition, the diameter W5 of the third through hole 421-3 provided in the third region R3 may be smaller than each of the diameter W3 of the first through hole 421-1 provided in the first region R1 and the diameter W4 of the second through hole 421-2 provided in the second region R2. In addition, the separation distance between two adjacent second through holes among the plurality of second through holes 421-2 may be smaller than each of the separation distance between two adjacent first through holes among the plurality of first through holes 421-1 and the separation distance W8 between two adjacent third through holes among the plurality of third through holes 421-3. In addition, the separation distance between two adjacent third through holes among the plurality of third through holes 421-3 may be greater than the separation distance between two adjacent first through holes among the plurality of first through holes 421-1 and the separation distance between two adjacent second through holes among the plurality of second through holes 421-2, respectively. Furthermore, the diameter of each through hole and the separation distance of each through hole may be greater than the width of the through electrode 430.

On the other hand, when the semiconductor package having the above-described characteristics of the invention is used in an IT device or home appliance such as a smart phone, a server computer, a TV, and the like, functions such as signal transmission or power supply can be stably performed. For example, the semiconductor package having the features of the present invention can function to safely protect the semiconductor device from external moisture or contaminants, or alternatively, it is possible to solve problems of leakage current, electrical short circuit between terminals, and electrical opening of terminals supplied to the semiconductor device. In addition, when the function of signal transmission is in charge, it is possible to solve the noise problem. Through this, the semiconductor package having the above-described characteristics of the invention can maintain the stable function of the IT device or home appliance, so that the entire product and the semiconductor package to which the present invention is applied can achieve functional unity or technical interlocking with each other.

When the semiconductor package having the characteristics of the invention described above is used in a transport device such as a vehicle, it is possible to solve the problem of distortion of a signal transmitted to the transport device, or alternatively, the safety of the transport device can be further improved by safely protecting the semiconductor device that controls the transport device from the outside and solving the problem of leakage current or electrical short between terminals or the electrical opening of the terminal supplied to the semiconductor device. Accordingly, the transportation device and the semiconductor package to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1.-10. (canceled)

11. A circuit board comprising:
an insulating layer;
a circuit layer disposed on the insulating layer and having an upper surface and a lower surface; and
a through electrode passing through at least a portion of the insulating layer along a vertical direction,
wherein the circuit layer includes a plurality of through holes passing through the upper surface and the lower surface,
wherein a diameter of each of the plurality of through holes equal to or greater than a separation distance between two through holes disposed adjacent to each other among the plurality of through holes, and
wherein the through electrode is in contact with the lower surface of the circuit layer including the plurality of through holes and does not overlap the plurality of through holes along the vertical direction.

12. The circuit board of claim 11, wherein diameters of each of the plurality of through holes are different from each other,
wherein a separation distance between two of the plurality of through-holes disposed adjacent to each other is different from each other, and
wherein a diameter of a smallest through hole among the plurality of through holes is equal to or greater than a largest separation distance among separation distances between two through holes disposed adjacent to each other.

13. The circuit board of claim 11, wherein a ratio of the diameter of the through hole to a planar area of the insulating layer satisfies a range of 0.0000825 to 0.000147.

14. The circuit board of claim 11, wherein a ratio of a planar area of the through hole to a planar area of the insulating layer satisfies a range of 0.00025905 to 0.0004605.

15. The circuit board of claim 13, wherein a planar area of the insulating layer is 1500 mm² to 2000 mm².

16. The circuit board of claim 13, wherein at least one of the plurality of through holes has a diameter of 165 μm to 220 μm.

17. The circuit board of claim 13, wherein a planar area of at least one of the plurality of through holes satisfies a range of 518.1 μm² to 690.8 μm².

18. The circuit board of claim 13, wherein the circuit layer includes a plurality of circuit patterns spaced apart in a horizontal direction,
wherein the plurality of through holes are provided in the plurality of circuit patterns, respectively, and
wherein a spacing between the plurality of circuit patterns is smaller than the diameter of the through hole.

19. The circuit board of claim 11, wherein the diameter of the through hole is greater than a width of the through electrode in a horizontal direction.

20. The circuit board of claim 19, wherein each of the plurality of through holes is not connected to an outer surface of the circuit layer.

21. The circuit board of claim 11, wherein the circuit layer includes a plurality of circuit patterns spaced apart in a horizontal direction, and
wherein at least one of the plurality of circuit patterns includes a first portion overlapping the plurality of through holes along the vertical direction and not overlapping the through electrode, and a second portion overlapping the through electrode along the vertical direction and not overlapping the plurality of through holes.

22. The circuit board of claim 11, wherein the insulating layer includes a lower insulating layer and an upper insulating layer disposed on the lower insulating layer,
wherein the circuit layer is disposed between the lower insulating layer and the upper insulating layer, and
wherein the plurality of through holes are filled with the upper insulating layer.

23. The circuit board of claim 19, wherein the circuit layer includes a first region including a plurality of first through holes, and a second region including a plurality of second through holes having a diameter smaller than a diameter of the plurality of first through holes.

24. The circuit board of claim 23, further comprising:
a lower wiring patterns disposed on a lower surface of the insulating layer,
wherein the lower wiring patterns includes a first lower wiring pattern overlapping the plurality of first through holes in the vertical direction, and a second lower wiring pattern overlapping the plurality of second through holes in the vertical direction, and
wherein a wiring density of the first lower wiring pattern and a wiring density of the second lower wiring pattern are different.

25. The circuit board of claim 24, wherein the wiring density of the second lower wiring pattern is greater than the wiring density of the first lower wiring pattern.

26. The circuit board of claim 25, wherein the second lower wiring pattern includes an impedance matching circuit pattern for impedance matching.

27. The circuit board of claim 24, wherein a separation distance between two first through holes closest to each other among the plurality of first through holes is greater than a separation distance between two second through holes closest to each other among the plurality of second through holes.

28. The circuit board of claim 27, wherein the circuit layer includes a third region closer to an edge of an upper surface of the circuit layer than the first region and the second region, and
wherein the third region includes a plurality of third through holes having a diameter smaller than the diameter of each of the first through hole and the second through hole.

29. The circuit board of claim 28, wherein a separation distance between two third through holes closest to each other among the plurality of third through holes is greater than a separation distance between two first through holes closest to each other among the plurality of first through holes and a separation distance between two second through holes closest to each other among the plurality of second through holes.

30. The circuit board of claim 23, wherein diameters of the plurality of first through holes are different from each other,
wherein separation distances between the plurality of first through holes are different from each other, and
wherein a smallest diameter among the diameters of the plurality of first through holes is greater than or equal to a largest separation distance among the separation distances between the plurality of first through holes.
